(19) United States
(12) Patent Application Publication
(10) Pub. No.: US 2017/0069470 A1
(43) Pub. Date: Mar. 9, 2017

(54) UPPER ELECTRODE STRUCTURE OF PLASMA PROCESSING APPARATUS, PLASMA PROCESSING APPARATUS, AND OPERATION METHOD THEREFOR

(71) Applicant: Tokyo Electron Limited, Tokyo (JP)

(72) Inventors: Koichi Murakami, Kurokawa-gun, Miyagi (JP); Michishige Saito, Kurokawa-gun, Miyagi (JP); Keita Kambara, Kurokawa-gun, Miyagi (JP); Kenji Nagai, Kurokawa-gun, Miyagi (JP)

(21) Appl. No.: 15/303,274

(22) PCT Filed: Apr. 28, 2015
(86) PCT No.: PCT/JP2015/062802

§ 371 Date: Oct. 11, 2016

(30) Foreign Application Priority Data
May 12, 2014 (JP) 2014-098809

(51) Int. Cl. H01J 37/32

(52) U.S. Cl. CPC H01J 37/32541; H01J 37/32091; H01J 37/32449; H01J 37/32522; H01J 2237/002; H01J 37/32183

(57) ABSTRACT

An upper electrode structure includes a first plate, a second plate and an electrostatic attraction unit. The first plate has a first region, a second region and a third region which are concentrically arranged. Each of the regions is provided with a multiple number of gas discharge openings. The electrostatic attraction unit is provided between the first plate and the second plate and is configured to attract the first plate. The electrostatic attraction unit is equipped with a first to third heaters for the first to third regions. The electrostatic attraction unit and the second plate provide a first supply path, a second supply path and a third supply path through which gases are supplied into the first to third regions, respectively. A first gas diffusion space, a second gas diffusion space and a third gas diffusion space are formed in the electrostatic attraction unit.

### TECHNICAL FIELD

The various embodiments described herein pertain generally to a plasma processing apparatus, an upper electrode structure of the plasma processing apparatus, and an operation method for the plasma processing apparatus.

### BACKGROUND ART

As a plasma processing apparatus for use in manufacturing an electronic device such as a semiconductor device, there is known a capacitively coupled plasma processing apparatus. In general, the capacitively coupled plasma processing apparatus is equipped with a processing vessel, a mounting table and an upper electrode structure. The mounting table is provided in the processing vessel, and is configured to support a processing target object. The mounting table includes a lower electrode. The upper electrode structure is disposed above the mounting table. Further, the upper electrode structure constitutes a shower head which is configured to supply a gas into the processing vessel.

The upper electrode structure has an electrode plate provided with a multiple number of gas discharge openings (i.e., first plate); and a backing plate configured to support the electrode plate (i.e., second plate). The first plate is fixed to the second plate with a clamp which presses a peripheral portion of the first plate against the second plate.

In the upper electrode structure using the clamp, however, when heat is applied to the upper electrode structure, a central portion of the first plate may not be in contact with the second plate or may be in contact with the second plate with a relatively weak force, though the peripheral portion of the first plate is in contact with the second plate. Thus, in the upper electrode structure using the clamp, uniform thermal conduction may not be achieved between the first plate and the second plate.

To solve this problem, there is proposed an upper electrode structure in which an electrostatic attracting device is provided between the first plate and the second plate, as disclosed in Patent Document 1. In the upper electrode structure described in Patent Document 1, the electrostatic attracting device has a supporting surface which is made of a flexible material. As the first plate is attracted to the supporting surface, uniform contact between the first plate and the electrostatic attracting device is obtained. Further, in this upper electrode structure, the electrostatic attracting device is provided with narrow gas lines which are continuous with the multiple number of gas discharge openings to allow a gas supply path formed in the backing plate and the multiple number of gas discharge openings to communicate with each other.

Patent Document 1: Japanese Patent No. 4,435,565

### DISCLOSURE OF THE INVENTION

### Problems to be Solved by the Invention

In the upper electrode structure described in Patent Document 1, the gas line formed in the electrostatic attracting device reduces conductance. Furthermore, in the upper electrode structure disclosed in Patent Document 1, there is still a room for improvement regarding temperature controllability over the electrode plate, though uniform contact between the electrode plate and the electrostatic attracting device can be achieved.

### Means for Solving the Problems

In one exemplary embodiment, there is provided an upper electrode structure of a capacitively coupled plasma processing apparatus. The upper electrode structure includes a first plate, a second plate and an electrostatic attraction unit. The first plate has a first region, a second region concentrically surrounding the first region, and a third region concentrically surrounding the second region. Each of the first region, the second region and the third region is provided with a multiple number of gas discharge openings. The second plate is provided with a flow path for a coolant. The electrostatic attraction unit is provided between the first plate and the second plate and is configured to attract the first plate. The electrostatic attraction unit is equipped with a first heater provided between the second plate and the first region, a second heater provided between the second plate and the second region and a third heater provided between the second plate and the third region. The electrostatic attraction unit provides, along with the second plate, a first supply path through which a gas is supplied into the first region, a second supply path through which a gas is supplied into the second region, and a third supply path through which a gas is supplied into the third region. A first gas diffusion space included in the first supply path, a second gas diffusion space included in the second supply path and a third gas diffusion space included in the third supply path are formed in the electrostatic attraction unit.

In the upper electrode structure according to the exemplary embodiment, the three concentrically arranged heaters are provided in the electrostatic attraction unit which is located directly above the first plate. Thus, this upper electrode structure has high controllability in a temperature of the first plate in a radial direction thereof. Generally, in the plasma processing apparatus, plasma having a plasma density distribution which differs in the radial direction with respect to an axis line which passes through a center of the first plate may be generated. Accordingly, the amount of the heat input to the first plate from the plasma has a distribution which differs in the radial direction. Further, due to this plasma density distribution, the etching amount of the first plate caused by a plasma process also has a distribution which varies in the radial direction. That is, as the plasma process is performed, the first plate becomes to have a thickness distribution. The thickness distribution of the first plate causes a varying temperature distribution of the first plate. In the upper electrode structure according to the exemplary embodiment, even if there exist these problems, that is, even if the heat input amount distribution and the thickness distribution of the first plate according to the plasma density distribution are generated, the temperature distribution of the first plate which varies in the radial direction can be corrected.

Further, in the upper electrode structure according to the exemplary embodiment, since the first gas diffusion space, the second gas diffusion space and the third gas diffusion space are provided in the electrostatic attraction unit which is disposed between the first plate and the second plate, it is possible to suppress reduction of conductance that might be caused by providing the electrostatic attraction unit.

The electrostatic attraction unit may include a main body made of ceramic and an electrode for electrostatic attraction, and a surface of the main body made of ceramic may form an attraction surface of the first plate. In this exemplary embodiment, the surface of the main body made of ceramic having relatively high hardness serves as the attraction surface. As a gas is introduced into a gap between the first plate and the electrostatic attraction unit, the gas accelerates a heat transfer between the first plate and the electrostatic attraction unit.

The first supply path is formed of a first gas line, a fourth gas diffusion space, a plurality of second gas lines, a fifth gas diffusion space, a plurality of third gas lines and the first gas diffusion space which are connected in sequence. The plurality of second gas lines and the plurality of third gas lines are arranged in a circumferential direction with respect to a central axis line of the first region, and have a conductance lower than a conductance of the first gas diffusion space, a conductance of the fourth gas diffusion space and a conductance of the fifth gas diffusion space. The second supply path is formed of a fourth gas line, a sixth gas diffusion space, a plurality of fifth gas lines, a seventh gas diffusion space, a plurality of sixth gas lines and the second gas diffusion space which are connected in sequence. The plurality of fifth gas lines and the plurality of sixth gas lines are arranged in the circumferential direction with respect to the central axis line, and have a conductance lower than a conductance of the second gas diffusion space, a conductance of the sixth gas diffusion space and a conductance of the seventh gas diffusion space. The third supply path is formed of a seventh gas line, an eighth gas diffusion space, a plurality of eighth gas lines, a ninth gas diffusion space, a plurality of ninth gas lines and the third gas diffusion space which are connected in sequence. The plurality of eighth gas lines and the plurality of ninth gas lines are arranged in the circumferential direction with respect to the central axis line, and have a conductance lower than a conductance of the third gas diffusion space, a conductance of the eighth gas diffusion space and a conductance of the ninth gas diffusion space.

A composite conductance of the first supply path dominantly depends on the conductance of the second gas lines and the conductance of the third gas lines. Further, the conductance of the second gas lines and the conductance of the third gas lines contribute to the composite conductance from the connection position of the first gas line and the fourth gas diffusion space to each of the gas discharge openings of the first region substantially to the same degree. Accordingly, it is possible to reduce a difference between the composite conductances from the first gas line to the gas discharge openings of the first region. Likewise, for the second supply path, it is possible to reduce a difference between the composite conductances from the second gas line to the gas discharge openings of the second region, and for the third supply path, it is possible to reduce a difference between the composite conductances from the third gas line to the gas discharge openings of the third region. Accordingly, differences in flow rates of the gases discharged from the gas discharge openings of each of the first region, second region and third region may be reduced.

Further, in this exemplary embodiment, each of the first supply path, the second supply path and the third supply path include three gas diffusion spaces. Accordingly, a difference in volumes of these supply paths can be reduced. Therefore, it is possible to reduce a difference in times taken until the gases are discharged from the gas discharge openings of the corresponding regions after the gases are supplied into the supply paths.

In another exemplary embodiment, there is provided a capacitively coupled plasma processing apparatus. The plasma processing apparatus includes a processing vessel; a mounting table which has a lower electrode and is provided within the processing vessel; and an upper electrode structure as described in any one of the above exemplary embodiment.

The plasma processing apparatus may include a first acquisition unit configured to irradiate light from a light source to the first region of the first plate and acquire a wavelength spectrum of reflection light from a front surface and a rear surface of the first region; a second acquisition unit configured to irradiate light from a light source to the second region of the first plate and acquire a wavelength spectrum of reflection light from a front surface and a rear surface of the second region; a third acquisition unit configured to irradiate light from a light source to the third region of the first plate and acquire a wavelength spectrum of reflection light from a front surface and a rear surface of the third region; and a processing unit configured to calculate an optical path length between the front surface and the rear surface of the first region, an optical path length between the front surface and the rear surface of the second region and an optical path length between the front surface and the rear surface of the third region based on the wavelength spectrum acquired by the first acquisition unit, the wavelength spectrum by the second system and the wavelength spectrum by the third acquisition unit, respectively. According to the present exemplary embodiment, by measuring the optical path length of each region, replacement time of the first plate can be detected. Further, the plasma processing apparatus of this exemplary embodiment may be configured to output an alarm when the optical path length of each region becomes a preset length.

The plasma processing apparatus may further include a first heater power supply connected to the first heater; a second heater power supply connected to the second heater; a third heater power supply connected to the third heater; and a controller configured to control the first heater power supply, the second heater power supply and the third heater power supply. The processing unit may calculate a temperature calculation value of the first region, a temperature calculation value of the second region and a temperature calculation value of the third region based on the optical path length of the first region, the optical path length of the second region and the optical path length of the third region, respectively, and the controller may control the first heater power supply, the second heater power supply and the third heater power supply based on the temperature calculation value of the first region, the temperature calculation value of the second region and the temperature calculation value of the third region, respectively. According to the present exemplary embodiment, it is possible to correct the temperature of each region by controlling the heater power supply corresponding to each region based on the temperature calculation value of each region of the first plate.

The controller may control the first heater power supply, the second heater power supply and the third heater power supply such that a temperature of the first region, a temperature of the second region and a temperature of the third region are substantially same. According to the present exemplary embodiment, it is possible to correct the temperature distribution which may be generated in the first plate.

The controller may control, when a plasma process is performed, the first heater power supply, the second heater power supply and the third heater power supply such that a temperature of the first region, a temperature of the second region and a temperature of the third region reach a preset temperature. In case of processing the multiple number of processing target objects in sequence, a plasma state when processing each processing target object may be varied. For example, a plasma state when processing the first processing target object may be different from a plasma state when processing a subsequent processing target object. This phenomenon is referred to as “first wafer effect.” Due to this phenomenon, the temperature of the upper electrode structure may be varied while processing the respective processing target objects. According to the exemplary embodiment, the temperature of the first region, the temperature of the second region and the temperature of the third region when the plasma process is performed may be controlled to become a preset temperature based on the temperature calculation values. Thus, it is possible to reduce a difference in the temperatures of the upper electrode structure while processing the processing target objects.

The controller may control the first heater power supply, the second heater power supply and the third heater power supply such that a temperature of the first region, a temperature of the second region and a temperature of the third region are respectively increased based on a ratio of an amount of a deposition gas to an amount of an etching gas, which are included in each of a first gas discharged from the gas discharge openings of the first region, a second gas discharged from the gas discharge openings of the second region and a third gas discharged from the gas discharge openings of the third region. Here, if a deposit originated from the deposition gas adheres to the surface of the first plate, the deposit may become a micro mask, and there may occur a phenomenon that the surface of the first plate is etched, that is, a so-called “black silicon” is formed. Formation of this black silicon becomes conspicuous depending on how much deposition gas is included in the gas, that is, depending on the ratio of the deposition gas in the certain gas. Meanwhile, an adhesion amount of the deposit decreases as the temperature of the first plate increases. According to the exemplary embodiment, since the temperatures of the regions are controlled based on the amount of the deposition gas included in each of the gases discharged from the corresponding gas discharge openings of the regions, it is possible to suppress the formation of black silicon in these regions.

In yet another exemplary embodiment, there is provided an operation method of the plasma processing apparatus as described above. The operation method includes controlling, when a plasma process is performed, the first heater power supply, the second heater power supply and the third heater power supply such that a temperature of the first region, a temperature of the second region and a temperature of the third region are substantially same.

In still yet another exemplary embodiment, the operation method includes controlling, when a plasma process is performed, the first heater power supply, the second heater power supply and the third heater power supply such that a temperature of the first region, a temperature of the second region and a temperature of the third region are substantially same.

In still yet another exemplary embodiment, the operation method includes controlling the first heater power supply, the second heater power supply and the third heater power supply such that a temperature of the first region, a temperature of the second region and a temperature of the third region are increased based on a ratio of an amount of a deposition gas to an amount of an etching gas, which are included in each of a first gas discharged from the gas discharge openings of the first region, a second gas discharged from the gas discharge openings of the second region and a third gas discharged from the gas discharge openings of the third region.

### Effect of the Invention

As stated above, even if the electrostatic attracting unit is provided in the upper electrode structure, the gas line is capable of suppressing reduction of conductance. Further, temperature controllability in the first plate of the upper electrode structure can be improved.

### BRIEF DESCRIPTION OF THE DRAWINGS

FIG. 1 is a cross sectional view schematically illustrating a plasma processing apparatus according to an exemplary embodiment.

FIG. 2 is a cross sectional view schematically illustrating an upper electrode structure according to the exemplary embodiment.

FIG. 3 is a diagram illustrating a gas supply system according to the exemplary embodiment.

FIG. 4 is a cross sectional view of the upper electrode structure seen from a line IV-IV of FIG. 2 in a direction indicated by corresponding arrows.

FIG. 5 is a perspective view showing a state where a first member and a second member of the upper electrode structure are connected.

FIG. 6 is an exploded perspective view illustrating the first member and the second member of the upper electrode structure.

FIG. 7 is a cross sectional view of the upper electrode structure seen from a line VII-VII of FIG. 2 in a direction indicated by corresponding arrows.

FIG. 8 is a cross sectional view of the upper electrode structure seen from a line VIII-VIII of FIG. 2 in a direction indicated by corresponding arrows.

FIG. 9 is a cross sectional view of the upper electrode structure seen from a line IX-IX of FIG. 2 in a direction indicated by corresponding arrows.

FIG. 10 is a flowchart for describing calculation of an optical path length.

FIG. 11 is a flowchart illustrating an example of an operation method for a plasma processing apparatus according to the exemplary embodiment.

FIG. 12 is a graph showing an experimental result of Experimental example 2.

### DETAILED DESCRIPTION

In the following, exemplary embodiments will be described in detail, and reference is made to the accompanying drawings, which form a part of the description. In the drawings, same or corresponding parts will be assigned same reference numerals.

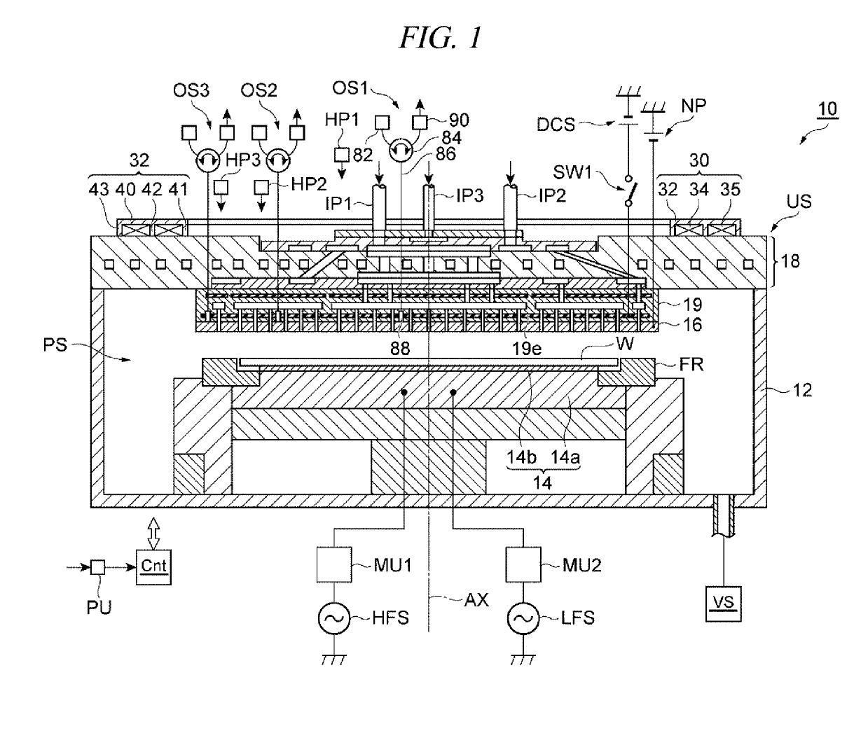

FIG. 1 is a cross sectional view schematically illustrating a plasma processing apparatus according to an exemplary embodiment. A plasma processing apparatus 10 shown in FIG. 1 is configured as a capacitively coupled plasma processing apparatus. The plasma processing apparatus 10 is equipped with a processing vessel 12. The processing vessel 12 has a substantially cylindrical shape and has a processing space PS formed therein. The processing space PS can be decompressed by a gas exhaust device VS.

A mounting table 14 is provided within the processing vessel PS. The mounting table 14 is equipped with a base 14a and an electrostatic chuck 14b. The base 14a is formed of a conductive member such as aluminum and has a substantially disk shape. A focus ring FR is provided on a peripheral portion of a top surface of the base 14a to surround an edge of a processing target object (hereinafter, referred to as “wafer W”). Further, the electrostatic chuck 14b is disposed on a central portion of the top surface of the base 14a.

The electrostatic chuck 14b has an electrode film which is provided as an inner layer embedded in an insulating film, for example, and has a substantially disk shape. The electrostatic chuck 14b is configured to attract the wafer W by an electrostatic force which is generated by a DC voltage supplied to the electrode film from a DC power supply via a switch. A top surface of the electrostatic chuck 14b constitutes a mounting area on which the wafer W is mounted. The wafer W is mounted on the mounting area of the electrostatic chuck 14b such that a center of the wafer W substantially coincides with an axis line AX which passes through a center of the mounting area in a vertical direction.

The base 14a serves as a lower electrode. A high frequency power supply HFS configured to generate a high frequency power for plasma generation is connected to the base 14a via a first matching device MU1. The high frequency power supply HFS generates a high frequency power of, e.g., 100 MHz. Further, the first matching device MU1 is equipped with a circuit for matching an output impedance of the first matching device MU1 and an input impedance at a load side (lower electrode side). Further, the high frequency power supply HFS may be connected to an upper electrode structure US which forms an upper electrode.

Furthermore, a high frequency power supply LFS configured to generate a high frequency bias power for ion attraction is connected to the base 14a via a second matching device MU2. The high frequency power supply LFS generates a high frequency power of, e.g., 3.2 MHz. Further, the second matching device MU2 is equipped with a circuit for matching an output impedance of the second matching device MU2 and an input impedance at the load side (lower electrode side).

The upper electrode structure US is disposed above the mounting table 14 to face the mounting table 14 with the processing space PS therebetween. The upper electrode structure US also serves as a shower head configured to introduce a gas into the processing space PS. In the plasma processing apparatus 10, if the gas is introduced from the upper electrode structure US and the high frequency power is supplied to the base 14a, a high frequency electric field is formed between the upper electrode structure US and the base 14a, and plasma is generated within the processing space PS. Further, in the exemplary embodiment, a DC power supply NP is connected to the upper electrode structure US. The DC power supply NP is capable of applying a negative DC voltage to the upper electrode structure US, for example, to a first plate 16 to be described later. Details of the upper electrode structure US will be described later.

Further, an electromagnet 30 is placed on the upper electrode structure US. The electromagnet 30 includes a core member 32, a coil 34 and a coil 35. The core member 32 has a structure in which a base portion 40 and cylindrical portions 41 to 43 are formed as one body. The core member 32 is made of a magnetic material. The base portion 40 has a substantially annular plate shape, and a central axis line thereof substantially coincides with the axis line AX. The cylindrical portions 41 to 43 are extended downwards from a bottom surface of the base portion 40. Each of the cylindrical portions 41 to 43 has a cylindrical shape, and a central axis line thereof coincides with the axis line AX. The cylindrical portion 42 is provided at an outside of the cylindrical portion 41, and the cylindrical portion 43 is provided at an outside of the cylindrical portion 42. Lower ends of these cylindrical portions 41 to 43 are located at positions above an outside of the edge of the wafer W.

A groove is formed between the cylindrical portion 41 and the cylindrical portion 42. The coil 34 wound along an outer surface of the cylindrical portion 41 is accommodated in this groove. Further, another groove is formed between the cylindrical portion 42 and the cylindrical portion 43, and the coil 35 wound along an outer surface of the cylindrical portion 42 is accommodated in this groove. Both ends of the coil 34 and both ends of the coil 35 are connected to a current source. If an electric current is applied to the coil 34 and/or the coil 35 from the current source, a magnetic field containing a horizontal magnetic component in a radial direction with respect to the axis line AX is generated in a region under the electromagnet 30 within the processing space PS.

In the plasma processing apparatus 10, there may be generated a plasma density distribution in which plasma density increases in the vicinity of the axis line AX and the plasma density decreases as it goes farther from the axis line AX. The magnetic field generated by the electromagnet 30 can allow this plasma density distribution to be uniform. That is, if the aforementioned magnetic field having the horizontal magnetic component is formed by the electromagnet 30, a Lorentz force which is based on the horizontal magnetic component is applied to electrons. Accordingly, the electrons drift in a circumferential direction with respect to the axis line AX. As stated above, since the lower ends of the cylindrical portions 41 to 43 are located at the positions above the outside of the edge of the wafer W, the magnetic field containing the horizontal magnetic component is generated at a position above the outside of the edge of the wafer W, so that the electrons drift in the circumferential direction in a region above the outside of the edge of the wafer W. Dissociation of the gas is accelerated in the region above the outside of the edge of the wafer W by the drifting electrons, so that the plasma density in the region above the outside of the edge of the wafer W can be increased. Thus, with the electromagnet 30, the plasma density distribution can be uniformed in the radial direction with respect to the axis line AX.

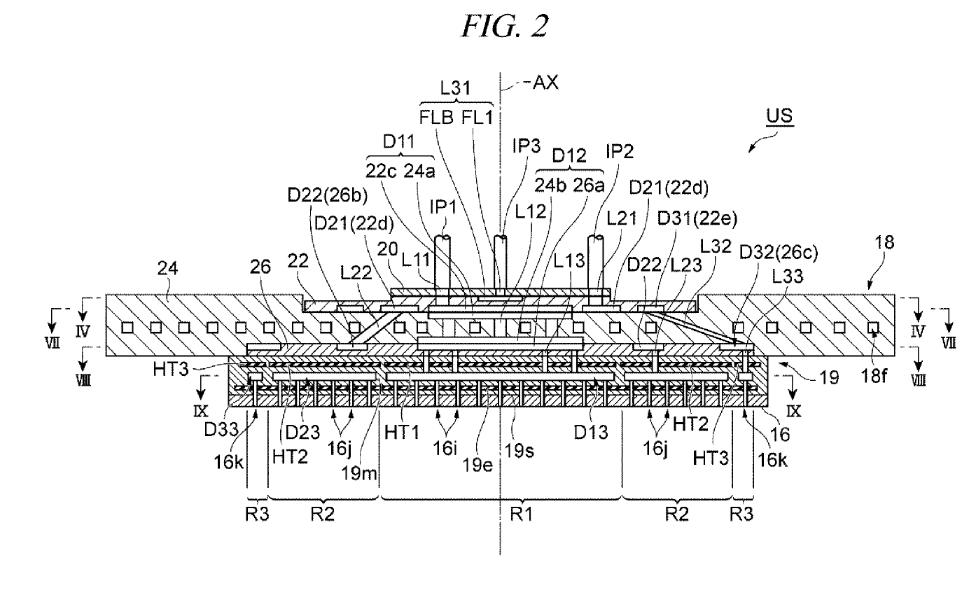

FIG. 2 is a cross sectional view schematically illustrating the upper electrode structure according to the exemplary embodiment. Below, reference is made to FIG. 1 and FIG. 2 together. The upper electrode structure US includes the first plate 16, a second plate 18 and an electrostatic attraction unit 19. The first plate 16 has a substantially disk shape, and a center of the first plate 16 coincides with the axis line AX. The first plate 16 faces the mounting table 14 with the processing space PS therebetween. That is, a bottom surface of the first plate 16 is in contact with the processing space PS. The first plate 16 is made of, by way of non-limiting example, silicon.

The first plate 16 includes a first region R1, a second region R2 and a third region R3 which are concentrically arranged. When viewed from the top, the first region R1 has a substantially circular region, and a center of the first region R1 is located on the axis line AX. The first region R1 is provided to face a region from a center of the wafer W to a midway position between the center and the edge of the wafer W. Multiple gas discharge openings 16i are formed in the first region R1. These gas discharge openings 16i are substantially uniformly distributed in the first region R1.

The second region R2 is a region surrounding the first region R1 and is extended in a substantially annular shape. The second region R2 faces a region from the midway position to the edge of the wafer W. Multiple gas discharge openings 16j are formed in this second region R2. These gas discharge openings 16j are substantially uniformly distributed in the second region R2.

Further, the third region R3 is a region surrounding the second region R2 and is extended in a substantially annular shape. The third region R3 is provided to face a region outside the edge of the wafer W, for example, to face the focus ring FR. Multiple gas discharge openings 16k are formed in this third region R3. These gas discharge openings 16k are substantially uniformly arranged in the third region R3.

A gas is supplied into the first region R1, the second region R2 and the third region R3 individually. To this end, in the plasma processing apparatus 10, a first supply path for supplying the gas to the first region R1, a second supply path for supplying the gas to the second region R2 and a third supply path for supplying the gas to the third region R3 are provided in the second plate 18 and the electrostatic attraction unit 19. Details of these supply paths will be elaborated later.

The second plate 18 has a substantially disk shape. The second plate 18 is made of, by way of example, but not limitation, aluminum and/or stainless steel. The second plate 18 is provided with a flow path 18f. The flow path 18f is formed in, for example, a spiral shape over the entire region of the second plate 18. A coolant from an external chiller unit is supplied into the flow path 18f. The coolant supplied into the flow path 18f is returned back into the chiller unit.

The electrostatic attraction unit 19 is disposed between the second plate 18 and the first plate 16. The electrostatic attraction unit 19 is fixed to a bottom surface of the second plate 18 with a clamp, for example. The electrostatic attraction unit 19 is configured to attract the first plate 16 by an electrostatic force.

The electrostatic attraction unit 19 includes a main body 19m and an electrode 19e. The main body 19m is made of ceramic and has a substantially disk shape. The main body 19m has a bottom surface, that is, a surface 19s. The surface 19s is a part of the main body 19m and is accordingly made of ceramic. The surface 19s serves as an attraction surface which attracts the first plate 16. Further, in the electrostatic attraction unit 19, the electrode 19e is provided as an inner layer embedded in the main body 19m. When viewed from the top, the electrode 19e is a thin film having a substantially circular shape. The electrode 19e is connected to a DC power supply DCS via a switch SW1. If a DC voltage is applied to the electrode 19e from the DC power supply DCS, an electrostatic force such as a Coulomb force is generated, and the first plate 16 is attracted to the surface 19s of the electrostatic attraction unit 19 by this electrostatic force.

An attracting force of the electrostatic attraction unit 19, that is, a surface pressure for attracting the first plate 16 is 3.25×10⁴ Pa when a voltage of 3 KV is applied to the electrode 19e, for example. Meanwhile, in case that the peripheral portion of the first plate is fixed with a clamp, as in the conventional upper electrode structure, the surface pressure becomes 2.76×10⁴ Pa if a clamping torque is set to be 2.0 N·m. Accordingly, the electrostatic attraction unit 19 is capable of holding the first plate 16 with a higher surface pressure. Furthermore, with this electrostatic attraction unit 19, a state in which a substantially entire surface of the first plate 16 is in contact with the surface 19s is maintained even when the heat is applied to the first plate 16, unlike the clamp at the peripheral portion. Thus, substantially uniform thermal conduction can be achieved over the entire surface of the first plate 16.

The main body 19m of the electrostatic attraction unit 19 is provided with a gas diffusion space D13 (first gas diffusion space), a gas diffusion space D23 (second gas diffusion space) and a gas diffusion space D33 (third gas diffusion space). The gas diffusion space D13 forms a part of the first supply path; the gas diffusion space D23, a part of the second supply path; and the gas diffusion space D33, a part of the third supply path. The gas diffusion space D13, the gas diffusion space D23 and the gas diffusion space D33 are disposed above the first region R1, the second region R2 and the third region R3, respectively. The gas diffusion space D13 has a substantially circular plane shape corresponding to the first region R1. Further, the gas diffusion space D23 is annularly extended to surround the gas diffusion space D13, and the gas diffusion space D33 is annularly extended to surround the gas diffusion space D23.

The gas diffusion space D13 communicates with the gas discharge openings 16i of the first region R1 and has a conductance larger than those of gas lines of the first supply path within the electrostatic attraction unit 19. The gas diffusion space D23 communicates with the gas discharge openings 16j of the second region R2 and has a conductance larger than that of a gas line of the second supply path within the electrostatic attraction unit 19. The gas diffusion space D33 communicates with the gas discharge openings 16j of the third region R3 and has a conductance larger than those of gas lines of the third supply path within the electrostatic attraction unit 19. As described, in this upper electrode structure US, the electrostatic attraction unit 19 is disposed between the first plate 16 and the second plate 18. Since, however, the gas diffusion space D13, the gas diffusion space D23 and the gas diffusion space D33 are formed in the electrostatic attraction unit 19, it is possible to suppress deterioration of the conductance of the first supply path, the second supply path and the third supply path within the electrostatic attraction unit 19.

Furthermore, since the main body 19m of the electrostatic attraction unit 19 is made of ceramic, it has high resistance against a corrosive gas for processing the wafer W. Since a part of the supply path such as the gas diffusion space D13, the gas diffusion space D23 and the gas diffusion space D33 is formed in this main body 19m, it is also possible to suppress particle generation. Further, since the gas diffusion space D13, the gas diffusion space D23 and the gas diffusion space D33 are formed in the main body 19m made of ceramic, concentration of the electric field within these gas diffusion spaces can be suppressed. Accordingly, it is possible to suppress abnormal discharge in the gas diffusion space D13, the gas diffusion space D23 and the gas diffusion space D33.

Within the electrostatic attraction unit 19, a first heater HT1, a second heater HT2 and a third heater HT3 are provided. The first heater HT1 is disposed above the first region R1. The second heater HT2 is provided above the second region R2 and is annularly extended to surround the first heater HT1. Further, the third heater HT3 is provided above the third region R3 and is annularly extended to surround the second heater HT2. The first heater HT1 is connected to a first heater power supply HP1; the second heater HT2, a second heater power supply HP2; and the third heater HT3, a third heater power supply HP3.

Here, plasma which is generated in the plasma processing apparatus generally has a plasma density distribution which differs in the radial direction with respect to the axis line AX. Accordingly, the amount of the heat input to the first plate 16 from the plasma has a distribution which differs in the radial direction. Further, due to this plasma density distribution, the etching amount of the first plate 16 caused by a plasma process also has a distribution which varies in the radial direction. That is, as the plasma process is performed, the first plate 16 becomes to have a thickness distribution. The thickness distribution of the first plate 16 causes a varying temperature distribution of the first plate 16. In the upper electrode structure US according to the exemplary embodiment, even if there exist these factors, that is, even if there are created the heat input amount distribution and the thickness distribution of the first plate 16 according to the plasma density distribution, the temperature distribution of the first plate 16 which varies in the radial direction can be corrected by the first heater HT1, the second heater HT2 and the third heater HT 3 which are concentrically arranged and provided directly above the first plate 16.

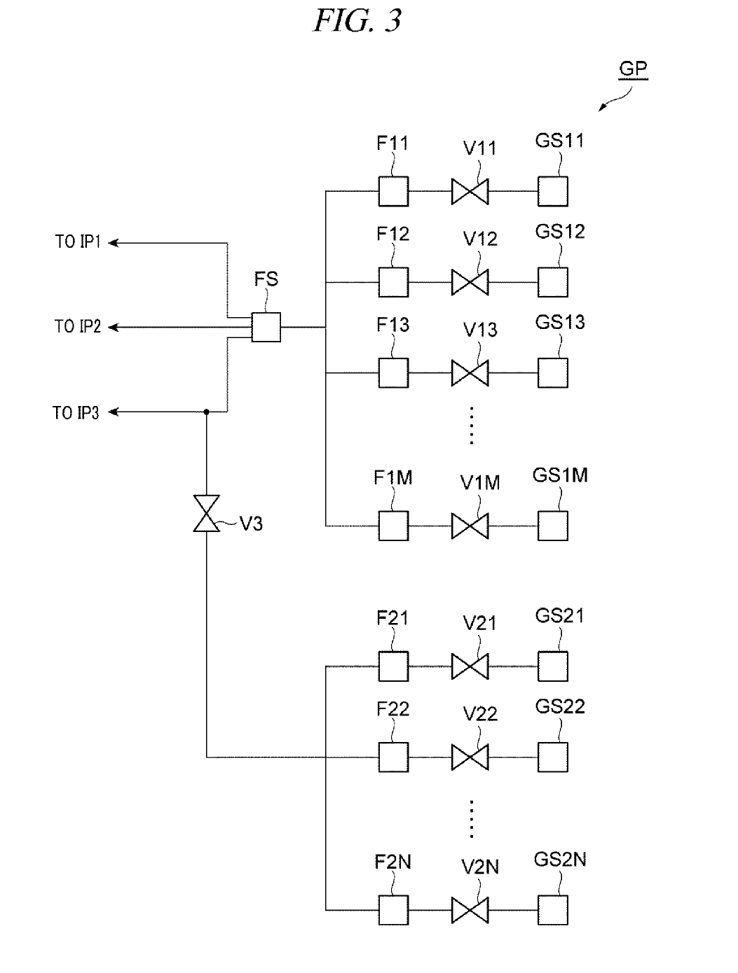

Now, the first supply path, the second supply path and the third supply path in the upper electrode structure US will be explained. The first supply path, the second supply path and the third supply path are configured to supply a gas from a gas supply system GP to the first region R1, the second region R2 and the third region R3, respectively. FIG. 3 is a diagram illustrating the gas supply system according to the exemplary embodiment. As depicted in FIG. 3, the gas supply system GP includes gas sources GS11 to GS1M, valves V11 to V1M, flow rate controllers F11 to F1M such as mass flow controllers, a flow splitter FS, gas sources GS21 to GS2N, valves V21 to V2N, flow rate controllers F21 to F2N such as mass flow controllers, and a valve V3.

The gas sources GS11 to GS1M are common gas sources to the first supply path, the second supply path and the third supply path. The gas sources GS11 to GS1M are connected to the flow splitter FS via the valves V11 to V1M and the flow rate controllers F11 to F1M, respectively. The flow splitter FS is configured to distribute a mixed gas from the gas sources GS11 to GS1M into a gas inlet line IP1, a gas inlet line IP2 and a gas inlet line IP3 at a preset distribution ratio.

The gas sources GS21 to GS2N are sources of additive gases and are connected to the valve V3 via the corresponding valves V21 to V2N and the corresponding flow rate controllers F21 to F2N, respectively. The valve V3 is connected to the gas inlet line IP3. Further, a mixed gas of the gas sources GS21 to GS2N may be supplied into the gas inlet line IP1 and the gas inlet line IP2 as well as the gas inlet line IP3.

Referring back to FIG. 2, the first supply path supplies the gas input from the gas supply system GP through the gas inlet line IP1 into the first region R1, that is, into the gas discharge openings 16i. The gas inlet line IP1 is connected to the first supply path at a position spaced apart from the axis line AX.

The second supply path supplies the gas input from the gas supply system GP through the gas inlet line IP2 into the second region R2, that is, into the gas discharge openings 16j. The gas inlet line IP2 is connected to the second supply path at a position spaced apart from the axis line AX.

The third supply path supplies the gas input from the gas supply system GP through the gas inlet line IP3 into the third region R3, that is, into the gas discharge openings 16k. The gas inlet line IP3 is connected to the third supply path at a position where it substantially coincides with the axis line AX.

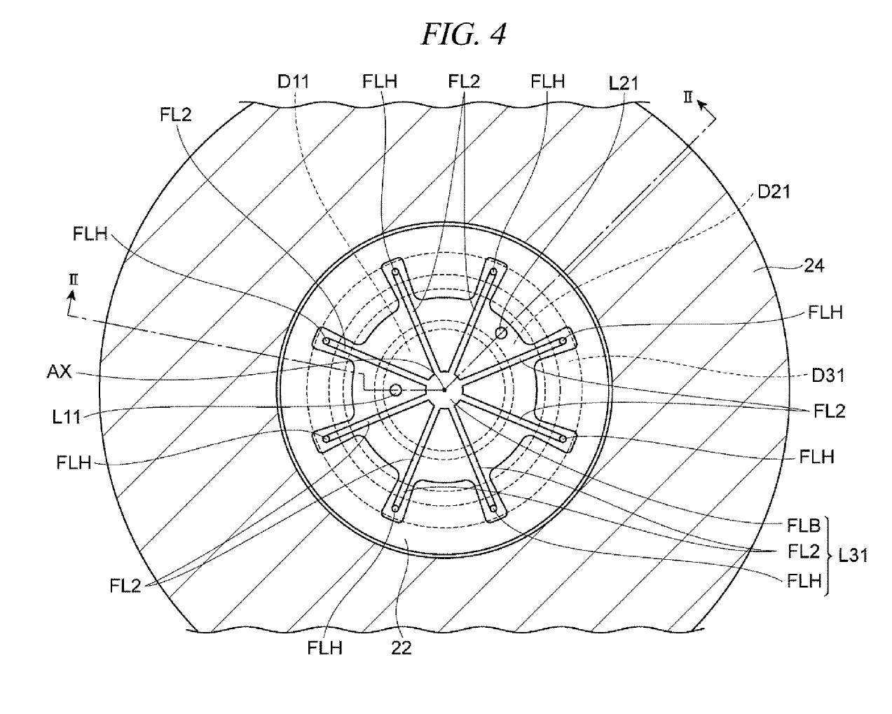

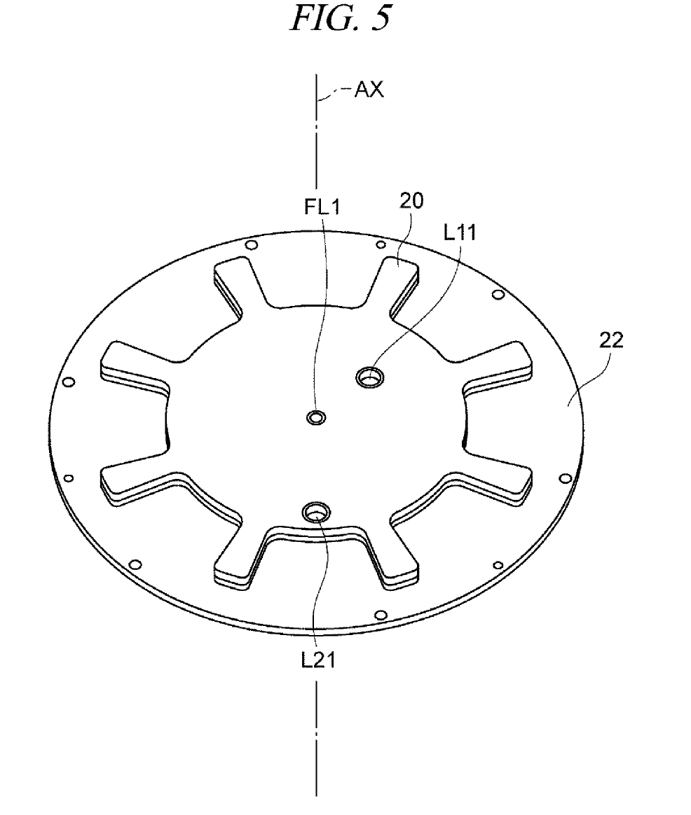

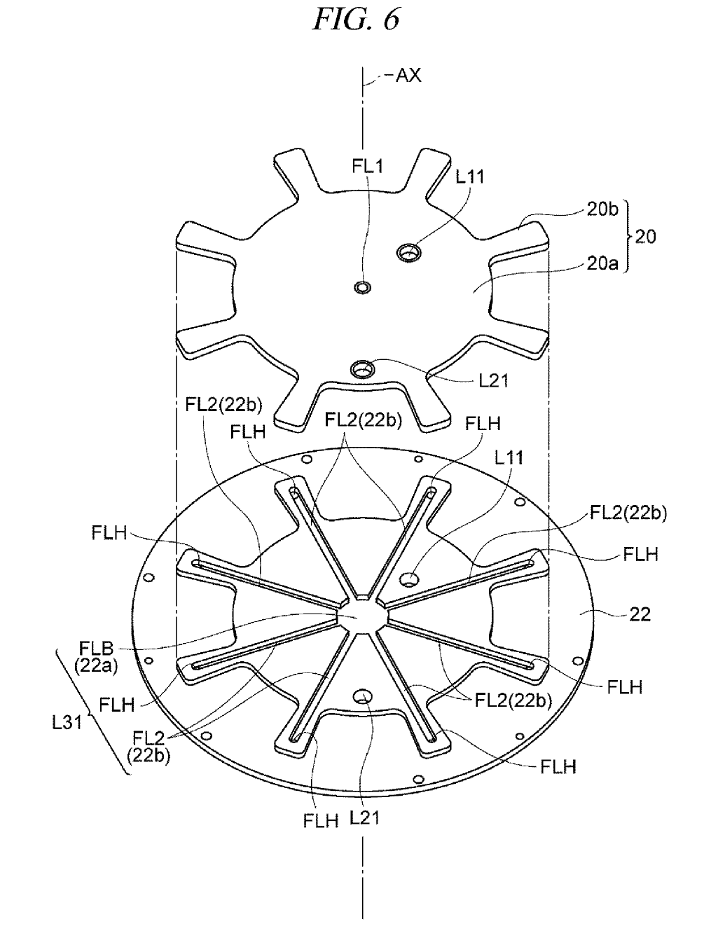

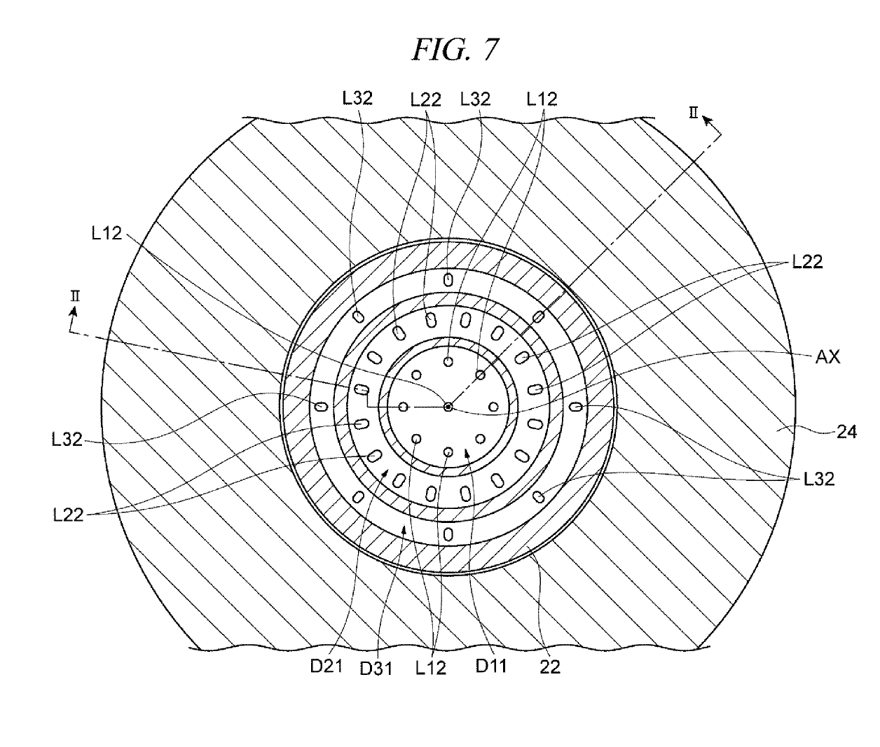

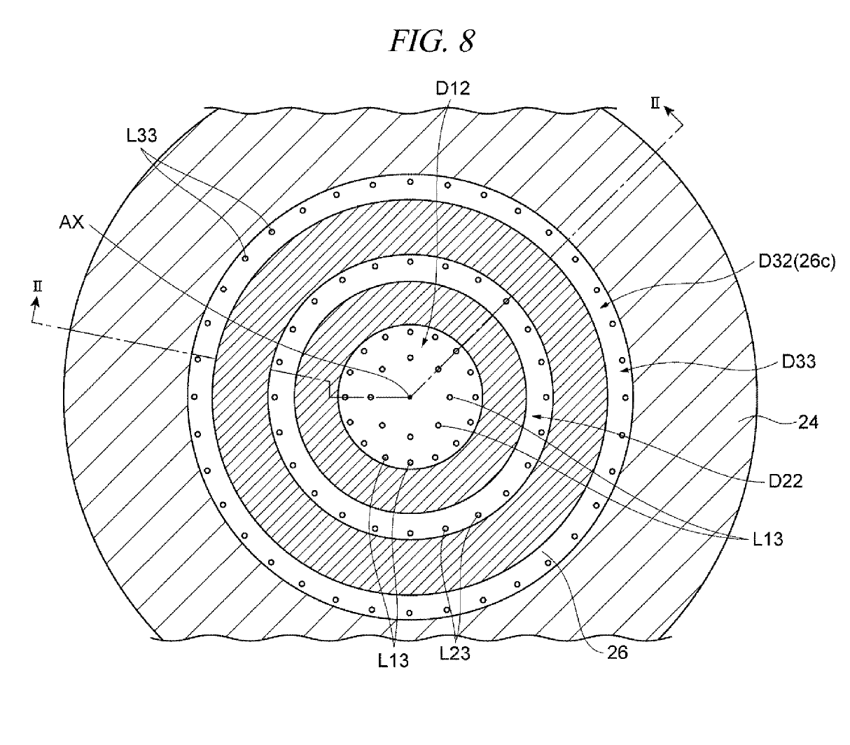

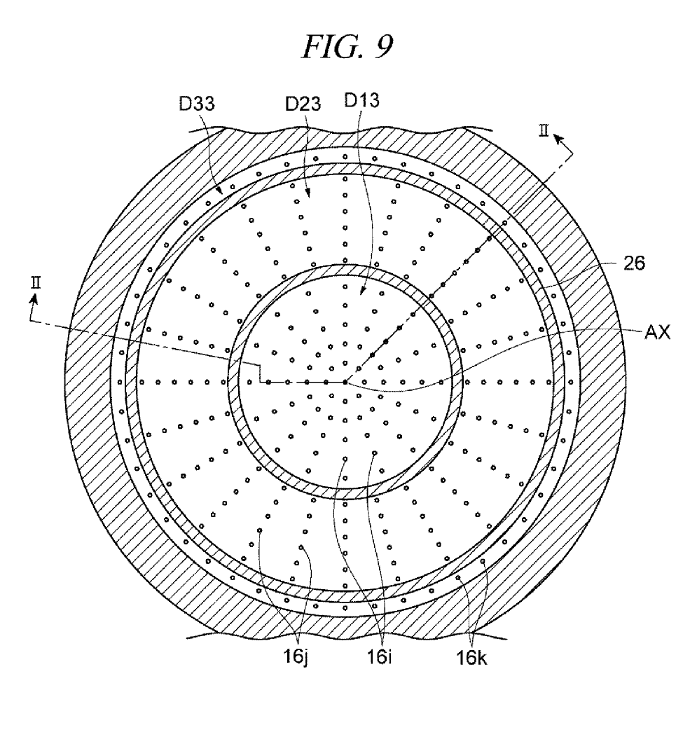

Below, reference is made to FIG. 4 to FIG. 9 as well as FIG. 1 and FIG. 2. FIG. 4 is a cross sectional view of the upper electrode structure seen from a line IV-IV of FIG. 2 in a direction indicated by corresponding arrows. FIG. 4 depicts a state where a cross section of the upper electrode structure which accords with the same plane as a top surface of a second member 22 to be described later is seen from above. FIG. 5 is a perspective view illustrating a state where a first member and the second member of the upper electrode structure are connected, and FIG. 6 is an exploded perspective view of the first member and the second member of the upper electrode structure. FIG. 7 is a cross sectional view of the upper electrode structure seen from a line VII-VII of FIG. 2 in a direction indicated by corresponding arrows. FIG. 7 illustrates a state where a cross section which transverses midway positions of the gas diffusion space D11, the gas diffusion space D21 and the gas diffusion space D31 in a height direction (i.e., direction of the axis line AX) is seen from above. FIG. 8 is a cross sectional view of the upper electrode structure seen from a VIII-VIII line of FIG. 2 in a direction indicated by corresponding arrows. FIG. 8 illustrates a state where a cross section which transverses midway positions of a gas diffusion space D12, a gas diffusion space D22 and a gas diffusion space D32 in the height direction is seen from above. FIG. 9 is a cross sectional view of the upper electrode structure seen from a line IX-IX of FIG. 2 in a direction indicated by corresponding arrows. FIG. 9 illustrates a state where a cross section which transverses midway positions of a gas diffusion space D13, a gas diffusion space D23 and a gas diffusion space D33 in the height direction is seen from above. Further, the cross sections shown in FIG. 1 and FIG. 2 correspond to longitudinal cross sections seen from a line II-II of FIG. 4 and FIG. 7 to FIG. 9.

As depicted in FIG. 1 and FIG. 2 and FIG. 4 to FIG. 9, the second plate 18 and the electrostatic attraction unit 19 of the upper electrode structure US provide, as constituent elements of the first supply path, a gas line L11 (first gas line), the gas diffusion space D11 (fourth gas diffusion space), a multiple number of gas lines L12 (second gas line), the gas diffusion space D12 (fifth gas diffusion space), a multiple number of gas lines L13 (third gas line) and the gas diffusion space D13 (first gas diffusion space). Further, the second plate 18 and the electrostatic attraction unit 19 of the upper electrode structure US provide, as constituent elements of the second supply path, a gas line L21 (fourth gas line), the gas diffusion space D21 (sixth gas diffusion space), a multiple number of gas lines L22 (fifth gas line), the gas diffusion space D22 (seventh gas diffusion space), a multiple number of gas lines L23 (sixth gas line) and the gas diffusion space D23 (second gas diffusion space). Furthermore, the second plate 18 and the electrostatic attraction unit 19 of the upper electrode structure US provide, as constituent elements of the third supply path, a gas line L31 (seventh gas line), the gas diffusion space D31 (eighth gas diffusion space), a multiple number of gas lines L32 (eighth gas line), the gas diffusion space D32 (ninth gas diffusion space), a multiple number of gas lines L33 (ninth gas lines) and the gas diffusion space D33 (third gas diffusion space).

The first supply path is formed of the gas line L11, the gas diffusion space D11, the multiple number of gas lines L12, the gas diffusion space D12, the multiple number of gas lines L13 and the gas diffusion space D13 which are connected in sequence from the upstream side thereof. The gas line L11, the gas diffusion space D11, the multiple number of gas lines L12 and the gas diffusion space D12 are formed in the second plate 18. Further, the multiple number of gas lines L13 are formed over the second plate 18 and the electrostatic attraction unit 19. Furthermore, the gas diffusion space D13 is formed in the electrostatic attraction unit 19.

The gas line L11 is connected to the gas inlet line IP1 at a position spaced apart from the axis line AX. This gas line L11 is connected to the gas diffusion space D11. As shown in FIG. 2 and FIG. 7, when viewed from the top, the gas diffusion space D11 is a substantially circular space, and a center of the gas diffusion space D11 coincides with the axis line AX. As depicted in FIG. 2, the gas diffusion space D12 is provided downstream of the gas diffusion space D11 and upstream of the gas diffusion space D13. That is, the gas diffusion space D12 is provided under the gas diffusion space D11, and the gas diffusion space D13 is provided under the gas diffusion space D12. The gas diffusions space D13 is provided directly above the first region R1 and is connected to the gas discharge openings 16i. As illustrated in FIG. 2, FIG. 8 and FIG. 9, when viewed from the top, the gas diffusion space D12 and the gas diffusion space D13 are both substantially circular spaces and their centers coincide with the axis line AX.

As depicted in FIG. 2, the multiple number of gas lines L12 are provided between the gas diffusion space D11 and the gas diffusion space D12. As shown in FIG. 2 and FIG. 7, the gas lines L12 are extended substantially in parallel with the axis line AX and arranged at a regular distance therebetween in the circumferential direction with respect to the axis line AX. Further, in the exemplary embodiment, one of the multiple number of gas lines L12 is extended on the axis line AX. One ends of the gas lines L12 are connected to the gas diffusion space D11, and the other ends of the gas lines L12 are connected to the gas diffusion space D12. These gas lines L12 have a conductance lower than a conductance of the gas diffusion space D11 and a conductance of the gas diffusion space D12.

As depicted in FIG. 2, the multiple number of gas lines L13 are provided between the gas diffusion space D12 and the gas diffusion space D13. As shown in FIG. 2 and FIG. 8, the multiple number of gas lines L13 are extended substantially in parallel with the axis line AX and arranged at a regular distance therebetween in the circumferential direction with respect to the axis line AX. In the exemplary embodiment, one of the multiple number of gas lines L13 is extended on the axis line AX. Further, in the exemplary embodiment, the others of the multiple number of gas lines L13 are arranged along two circles around the axis line AX with a regular distance therebetween in the circumferential direction. One ends of these gas lines L13 are connected to the gas diffusion space D12, and the other ends of the gas lines L13 are connected to the gas diffusion space D13. These gas lines L13 have a conductance lower than the conductance of the gas diffusion space D12 and a conductance of the gas diffusion space D13.

The second gas supply path is formed of the gas line L21, the gas diffusion space D21, the multiple number of gas lines L22, the gas diffusion space D22, the multiple number of gas lines L23 and the gas diffusion space D23 which are connected in sequence from the upstream side thereof. The gas line L21, the gas diffusion space D21, the multiple number of gas lines L22 and the gas diffusion space D22 are formed in the second plate 18. Further, the multiple number of gas lines L23 are formed over the second plate 18 and the electrostatic attraction unit 19. Furthermore, the gas diffusion space D23 is formed in the electrostatic attraction unit 19.

The gas line L21 is connected to the gas inlet line IP2 at a position spaced apart from the axis line AX. This gas line L21 is connected to the gas diffusion space D21. As shown in FIG. 2 and FIG. 7, the gas diffusion space D21 is a space which is extended in a substantially annular shape with respect to the axis line AX. The gas diffusion space D21 is extended in the circumferential direction at an outside of the gas diffusion space D11 with respect to the axis line AX. As depicted in FIG. 2, the gas diffusion space D22 is provided downstream of the gas diffusion space D21 and upstream of the gas diffusion space D23.

As illustrated in FIG. 2 and FIG. 8, the gas diffusion space D22 is a space which is extended around the axis line AX in a substantially annular shape. The gas diffusion space D22 is extended in the circumferential direction at an outside of and under the gas diffusion space D21. The gas diffusion space D22 is provided at an outside of the gas diffusion space D12 to surround the gas diffusion space D12. Further, the gas diffusion space D22 is extended while being spaced farther from the axis line AX than the gas diffusion space D21.

As shown in FIG. 2 and FIG. 9, the gas diffusion space D23 is provided directly above the aforementioned second region R2 and is connected to the gas discharge openings 16j. The gas diffusion space D23 is a space which is extended around the axis line AX in a substantially annular shape, and is extended under the gas diffusion space D22 in the circumferential direction with respect to the axis line AX. Further, the gas diffusion space D23 is extended to surround the gas diffusion space D13.

As depicted in FIG. 2, the multiple number of gas lines L22 are provided between the gas diffusion space D21 and the gas diffusion space D22. As shown in FIG. 2 and FIG. 7, the multiple number of gas lines L22 are extended to be distanced away from the axis line AX as they head downward, and arranged in the circumferential direction with respect to the axis line AX. In the exemplary embodiment, the multiple number of gas lines L22 are arranged at a regular distance therebetween in the circumferential direction with respect to the axis line AX. One ends of these gas lines L22 are connected to the gas diffusion space D21, and the other ends of the gas lines L22 are connected to the gas diffusion space D22. These gas lines L22 have a conductance lower than a conductance of the gas diffusion space D21 and a conductance of the gas diffusion space D22.

As illustrated in FIG. 2, the multiple number of gas lines L23 are provided between the gas diffusion space D22 and the gas diffusion space D23. As shown in FIG. 2 and FIG. 8, the multiple number of gas lines L23 are extended substantially in parallel with the axis line AX and arranged at a regular distance therebetween in the circumferential direction with respect to the axis line AX. One ends of these gas lines L23 are connected to the gas diffusion space D22, and the other ends of the gas lines L23 are connected to the gas diffusion space D23. These gas lines L23 have a conductance lower than the conductance of the gas diffusion space D22 and the conductance of the gas diffusion space D23.

The third supply path is formed of the gas line L31, the gas diffusion space D31, the multiple number of gas lines L32, the gas diffusion space D32, the multiple number of gas lines L33 and the gas diffusion space D33 which are connected in sequence from the upstream side thereof. The gas line L31, the gas diffusion space D31, the multiple number of gas lines L32 and the gas diffusion space D32 are formed in the second plate 18. Further, the multiple number of gas lines L33 are formed over the second plate 18 and the electrostatic attraction unit 19. Furthermore, the gas diffusion space D33 is formed in the electrostatic attraction unit 19.

As depicted in FIG. 2 and FIG. 4, the gas line L31 includes a first flow path FL1 and a plurality of second flow paths FL2. Further, in the exemplary embodiment, the gas line L31 has a gas branching portion FLB and a plurality of through holes FLH. The first flow path FL1 is extended on the axis line AX. One end of the first flow path FL1 is connected to the gas inlet line IP3, and the other end of the first flow path FL1 is connected to the gas branching portion FLB.

When viewed from the top, the gas branching portion FLB is a substantially circular space, and the second flow paths FL2 are branched from the first flow path FL1 at the gas branching portion FLB. That is, one ends of the second flow paths FL2 on the side of the axis line AX are connected to the first flow path FL1 via the gas branching portion FLB. Further, the second flow paths FL2 are extended in the radial direction with respect to the axis line AX and arranged at a regular distance in the circumferential direction with respect to the axis line AX. Furthermore, the other ends of the second flow paths FL2 are respectively connected to the through holes FLH which are extended substantially in parallel with the axis line AX. These through holes FLH are connected to the gas diffusion space D31 which is provided under the through holes FLH.

As shown in FIG. 2, FIG. 4 and FIG. 7, the gas diffusion space D31 is a space which is extended around the axis line AX in a substantially annular shape. The gas diffusion space D31 is extended in the circumferential direction at an outside of the gas diffusion space D21 with respect to the axis line AX. As shown in FIG. 2, the gas diffusion space D32 is provided downstream of the gas diffusion space D31 and upstream of the gas diffusion space D33.

As depicted in FIG. 2 and FIG. 8, the gas diffusion space D32 is a space which is extended around the axis line AX in a substantially annular shape. The gas diffusion space D32 is extended in the circumferential direction at an outside of and under the gas diffusion space D31. Further, the gas diffusion space D32 is provided at an outside of the gas diffusion space D22 to surround the gas diffusion space D22. Furthermore, the gas diffusion space D32 is extended while being spaced farther from the axis line AX than the gas diffusion space D31.

As shown in FIG. 2 and FIG. 9, the gas diffusion space D33 is provided directly above the aforementioned third region R3 and is connected to the gas discharge openings 16k. The gas diffusion space D33 is a space which is extended around the axis line AX in a substantially annular shape, and is extended in the circumferential direction to surround the gas diffusion space D23.

As depicted in FIG. 2, the multiple number of gas lines L32 are provided between the gas diffusion space D31 and the gas diffusion space D32. As shown in FIG. 2 and FIG. 7, the multiple number of gas lines L32 are diagonally extended to be distanced away from the axis line AX as they head downwards, and are arranged at a regular distance therebetween in the circumferential direction with respect to the axis line AX. One ends of these gas lines L32 are connected to the gas diffusion space D31, and the other ends of the gas lines L32 are connected to the gas diffusion space D32. These gas lines L32 have a conductance lower than a conductance of the gas diffusion space D31 and a conductance of the gas diffusion space D32.

As illustrated in FIG. 8, the multiple number of gas lines L33 are provided between the gas diffusion space D32 and the gas diffusion space D33. The multiple number of gas line L33 are extended substantially in parallel with the axis line AX and arranged at a regular distance therebetween in the circumferential direction with respect to the axis line AX. One ends of these gas lines L33 are connected to the gas diffusion space D32, and the other ends of the gas lines L33 are connected to the gas diffusion space D33. These gas lines L33 have a conductance lower than the conductance of the gas diffusion space D32 and the conductance of the gas diffusion space D33.

According to the exemplary embodiment, as shown in FIG. 2 and FIG. 4 to FIG. 9, the second plate 18 may be composed of a multiple number of members. To elaborate, the second plate 18 includes a first member 20 and a second member 22 constituting an upper member together; an intermediate member 24; and a lower member 26. The second plate 18 is formed of the upper member, the intermediate member 24 and the lower member 26 which are stacked on top of each other.

Each of the first member 20 and the second member 22 is made of stainless steel. As a top surface of the first member 20 and a bottom surface of the second member 22 are diffusion-bonded, the first member 20 and the second member 22 are joined as one body to constitute the upper member. As illustrated in FIG. 4 to FIG. 6, the second member 22 has a substantially disk shape, and a recess 22a serving as the gas branching portion FLB and a plurality of grooves 22b serving as the second flow paths FL2 are formed at a top surface of second member 22. One ends of the grooves 22b are connected to the recess 22a and are extended in the radial direction with respect to the axis line AX. Further, the second member 22 is provided with the plurality of through holes FLH, and each of the through holes FLH is connected to the other end of each corresponding one of the grooves 22b.

The first member 20 has a substantially disk-shaped central portion 20a and a plurality of protruding portions 20b extended from the central portion 20a in the radial direction. The first flow path FL1 is formed in the central portion 20a. The first flow path FL1 is connected to the recess 22a, that is, the gas branching portion FLB when the first member 20 and the second member 22 are bonded together. Further, the gas line L11 and the gas line L22 are formed through the first member 20 and the second member 22 such that they penetrate the first member 20 and the second member 22 in the direction of the axis line AX.

Further, the central portion 20a and the protruding portions 20b of the first member 20 are configured to close upper openings of the recess 22a and the grooves 22b when the first member 20 and the second member 22 are bonded to each other, so that the gas branching portion FLB and the second flow paths FL2 are formed. As described, as the first member 20 and the second member 22 are connected to each other by diffusion bonding, it is possible to form the gas line L11, the gas line L21 and the gas line L31 without using sealing members. As a result, the thickness of a complex body for forming these gas lines can be reduced.

As shown in FIG. 2 and FIG. 7, a recess 22c, a groove 22d and a groove 22e are formed at a bottom surface of the second member 22. When viewed from the top, the recess 22c is a space having a substantially circular shape. This recess 22c forms an upper portion of the gas diffusion space D11 if the upper member including the first member 20 and the second member 22 is mounted on the intermediate member 24. The groove 22d is extended around the axis line AX in the circumferential direction and is provided between the recess 22c and the groove 22e. The groove 22e having an annular shape is extended in the circumferential direction at an outside of the groove 22d. The annular groove 22d and the annular groove 22e form the gas diffusion space D21 and the gas diffusion space D31, respectively, if the upper member including the first member 20 and the second member 22 is mounted on the intermediate member 24.

As depicted in FIG. 2, the intermediate member 24 has a substantially disk shape and is made of a metal such as, but not limited to, aluminum. A recess 24a is formed at a top surface of the intermediate member 24. When viewed from the top, this recess 24a is a space having a substantially circular shape and is provided at an area which intersects with the axis line AX. If the upper member including the first member 20 and the second member 22 is mounted on the intermediate member 24, the recess 24a is continuous with the recess 22c to form a lower portion of the gas diffusion space D11. That is, this recess 24a serves as an extension area which extends the gas diffusion space D11.

Formed through the intermediate member 24 are the gas lines L12, the gas lines L22 and the gas lines L32. Further, a recess 24b is formed at a bottom surface of the intermediate member 24. When viewed from the top, the recess 24b is a space having a substantially circular shape and is provided at an area which intersects with the axis line AX. The recess 24b forms an upper portion of the gas diffusion space D12 if the intermediate member 24 is mounted on the lower member 26. That is, the recess 24b serves as an extension area which extends the diffusion space D12.

The lower member 26 has a substantially disk shape and is made of, by way of example, but not imitation, aluminum. A recess 26a, a groove 26b and a recess 26c are formed at a top surface of the lower member 26. When viewed from the top, the recess 26a is a space having a substantially circular shape and is provided at an area which intersects with the axis line AX. If the intermediate member 24 is mounted on the lower member 26, the recess 26a forms a lower portion of the gas diffusion space D12 while being continuous with the recess 24b of the intermediate member 24.

The groove 26b is extended around the axis line AX in the circumferential direction and is provided between the recess 26a and the recess 26c. The recess 26c is extended in the circumferential direction at an outside of the groove 26b. The groove 26b and the recess 26c form the gas diffusion space D22 and the gas diffusion space D32, respectively, if the intermediate member 24 is mounted on the lower member 26.

Further, as depicted in FIG. 2, the lower member 26 is provided with through holes which partially form the gas lines L13, through holes which partially form the gas lines L23 and through holes which partially form the gas lines L33. These through holes formed in the lower member 26 are connected to corresponding through holes of the electrostatic attraction unit 19 if the lower member 26 is connected to the electrostatic attraction unit 19, so that the gas lines L13, the gas lines L23 and the gas lines L33 are formed.

In the above-described first supply path of the upper electrode structure US, the multiple number of gas lines L12 having a low conductance and arranged in the circumferential direction are provided between the gas diffusion space D11 and the gas diffusion space D12, and the multiple number of gas lines L13 having a low conductance and arranged in the circumferential direction are provided between the gas diffusion space D12 and the gas diffusion space D13. Further, in the second supply path, the multiple number of gas lines L22 having a low conductance and arranged in the circumferential direction are provided between the gas diffusion space D21 and the gas diffusion space D22, and the multiple number of gas lines L23 having a low conductance and arranged in the circumferential direction are provided between the gas diffusion space D22 and the gas diffusion space D23. Furthermore, in the third supply path, the multiple number of gas lines L32 having a low conductance and arranged in the circumferential direction are provided between the gas diffusion space D31 and the gas diffusion space D32, and the multiple number of gas lines L33 having a low conductance and arranged in the circumferential direction are provided between the gas diffusion space D32 and the gas diffusion space D33.

In this upper electrode structure US, since the position where the gas lines L11 are connected to the gas diffusion space D11 is distanced away from the axis line AX, there is generated a difference between conductances from the position where the gas line L11 is connected to the gas diffusion space D11 to respective positions where the gas lines L12 are connected to the gas diffusion space D11. In this upper electrode structure US, however, a composite conductance from the connection position of the gas line L11 to the gas diffusion space D11 to each of the gas discharge openings 16i of the first region R1 dominantly depends on the conductance of the gas line L12 and the conductance of the gas line L13. Further, the conductance of the gas line L12 and the conductance of the gas line L13 contribute to the composite conductance from the gas line L11 to each of the gas discharge openings 16i of the first region R1 substantially to the same degree. Accordingly, a difference between the composite conductances from the connection position of the gas line L11 to the gas diffusion space D11 to the respective gas discharge openings 16i of the first region R1 is reduced, so that a difference in flow rates of the gas from the gas discharge openings 16i of the first region R1 is reduced. Likewise, a difference in flow rates of the gas from the gas discharge openings 16j of the second region R2 and a difference in flow rates of the gas from the gas discharge openings 16k of the third region R3 can also be reduced.

Moreover, since each of the first supply path, the second supply path and the third supply path includes three diffusion spaces, the volume of the first supply path, the volume of the second supply path and the volume of the third supply path can be made to be similar to each other. Here, a time taken until a gas is discharge from gas discharge openings after the gas is supplied into a gas supply path relies on the volume of the gas supply path. Thus, with the upper electrode structure US of the present exemplary embodiment, it is possible to reduce a difference in times taken until the gas is discharged from the corresponding gas discharge openings after the gas is supplied into the respective gas supply paths.

Referring back to FIG. 1, the plasma processing apparatus 10 includes a first acquisition unit OS1, a second acquisition unit OS2, a third acquisition unit OS3 and a processing unit PU. The first acquisition unit OS1 is configured to irradiate light to the first region R1 of the first plate 16 and receive reflection light from a front surface and a rear surface of the first region R1. The second acquisition unit OS2 is configured to irradiate light to the second region R2 of the first plate 16 and receive reflection light from a front surface and a rear surface of the second region R2. The third acquisition unit OS3 is configured to irradiate light to the third region R3 of the first plate 16 and receive reflection light from a front surface and a rear surface of the third region R3. In the exemplary embodiment, the first acquisition unit OS1 acquires wavelength spectrum of the received reflection light, the second acquisition unit OS2 acquires wavelength spectrum of the received reflection light, and the third acquisition unit OS3 acquires wavelength spectrum of the received reflection light.

The processing unit PU is configured to calculate an optical path length between the front surface (top surface in FIG. 1) and the rear surface (bottom surface in FIG. 1) of the first region R1 based on the wavelength spectrum acquired by the first acquisition unit OS1; calculate an optical path length between the front surface and the rear surface of the second region R2 based on the wavelength spectrum acquired by the second acquisition unit OS2; and calculate an optical path length between the front surface and the rear surface of the third region R3 based on the wavelength spectrum acquired by the third acquisition unit OS3. Here, the first acquisition unit OS1, the second acquisition unit OS2 and the third acquisition unit OS3 have the substantially same configuration, though they are configured to irradiate light to different areas. Thus, the first acquisition unit OS1, the second acquisition unit OS2 and the third acquisition unit OS3 will be generically referred to as “acquisition unit OS,” and the acquisition unit OS will be elaborate below. In the following description, the first region R1, the second region R2 and the third region R3 will be all referred to as the first plate 16 without being distinguished from each other.

The acquisition unit OS is equipped with a light source 82, a circulator 84, an optical fiber 86, an optical element 88 and a spectrometer 90. The light source 82 emits light. The light emitted by the light source 82 is irradiated to the first plate 16 and penetrates the first plate 16. The light emitted by the light source 82 is, by way of non-limiting example, infrared light and has a wavelength band ranging from 1510 nm to 1590 nm. The light output from the light source 82 is guided to the optical element 88 via the circulator 84 and the optical fiber 86.

The optical element 88 is implemented by a collimator or an optical condensing element. The optical element 88 is disposed to face the front surface (top surface in FIG. 1) of the first plate 16. The optical element 88 is configured to convert the light from the light source 82 to parallel light or condense the light. The optical element 88 is also configured to output the light from the light source 82 toward the first plate 16. Further, the optical fiber 86 and the optical element 88 may be provided within a pipe which penetrates the second plate 18 and the electrostatic attraction unit 19. Alternatively, the optical fiber 86 and the optical element 88 may be provided within through holes which are formed through the second plate 18 and the electrostatic attraction unit 19 without being overlapped with the gas lines of the second plate 18 and the electrostatic attraction unit 19. In such a case, the through holes may be formed through a crossbeam which is provided within the gas diffusion space.

The light output from the optical element 88 is reflected on the front surface (top surface in FIG. 1) and the rear surface (bottom surface in FIG. 1) of the first plate 16. A multiple number of reflection rays caused by the reflection at the front surface and the rear surface are introduced to the spectrometer 90 via the optical element 88, the optical fiber 86 and the circulator 84. The spectrometer 90 outputs a wavelength spectrum of the received reflection rays, i.e., reflection light. Further, the reflection rays interfere with each other, and enhance or weaken each other according to a wavelength involved. Accordingly, the wavelength spectrum output from the spectrometer 90 has a signal intensity which may vary depending on the wavelength involved. Furthermore, the spectrometer 90 may be implemented by a general spectrometer, or it may be equipped with a tunable filter, a light receiving element, an A/D converter and a wavelength controller, as disclosed in Japanese Patent Laid-open Publication No. 2013-096858. The wavelength spectrum obtained by the spectrometer 90 is output to the processing unit PU. The processing unit PU calculates an optical path length of the first plate 16 based on valley wavelength or a peak wavelength of a wavelength spectrum which is obtained by processing a first wavelength spectrum.

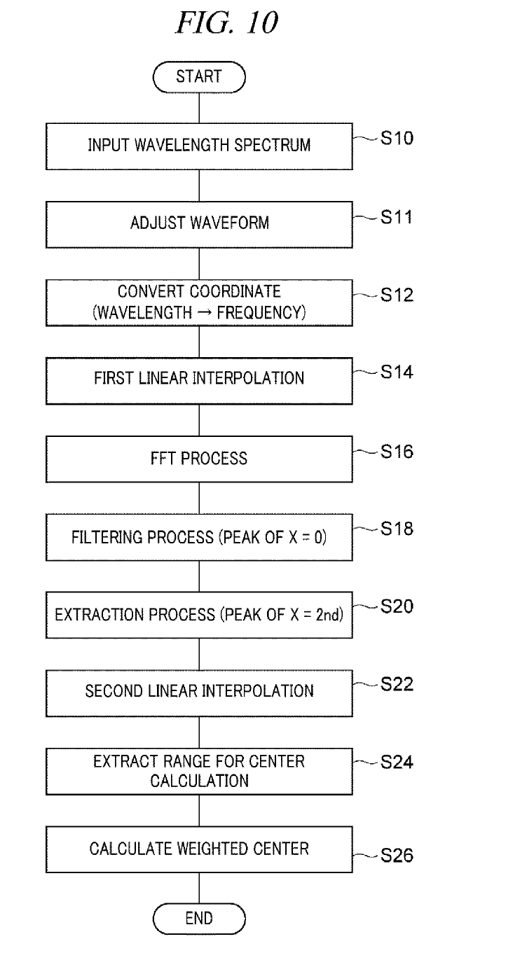

Hereinafter, a process in which the processing unit PU calculates the optical path length will be described in detail. FIG. 10 is a flowchart for describing the calculation of the optical path length. The processing unit PU calculates an optical path length nd between the front surface and the rear surface of the first plate 16 through the process described in FIG. 10. Here, n denotes a refractive index of the first plate 16, and d represents a plate thickness (distance between the front surface and the rear surface) of the first plate 16. To elaborate, as depicted in FIG. 10, the calculation of the optical path length by the processing unit PU starts from inputting a wavelength spectrum (S10). That is, the wavelength spectrum from the acquisition unit OS is input to the processing unit PU.

In a subsequent process S11, the processing unit PU adjusts a waveform of the received wavelength spectrum. That is, the processing unit PU applies a window function to the wavelength spectrum. This window function is wavelength-dependent. By way of example, in case that the spectrometer 90 has a wavelength sweeping unit, the window function may be a bell-shaped function in which a center wavelength determined by a wavelength sweeping range has a maximum value and a value of a wavelength decreases as a difference between the wavelength and the center wavelength increases. For example, a median value of the wavelength sweeping range is used as the center wavelength. Further, a Gaussian function, a Lorentz function, and a composite function of the Gaussian function and the Lorentz function may be used as the window function.

In a subsequent process S12, the processing unit PU converts a coordinate axis of the spectrum obtained in the process S11 from the wavelength λ to a spatial frequency 1/λ.

Then, in a process S14, the processing unit PU performs first data interpolation (first linear interpolation). That is, the processing unit PU performs data interpolation on the spectrum obtained in the process S12. By way of example, assume that the sampling number is Ns, and spatial frequencies are arranged to be x₀, x₁, x₂, . . . , x_{N-1} and intensities are arranged to be y₀, y₁, y₂, . . . , y_{N-1} as data of the spectrum. First, the processing unit PU re-arranges the spatial frequencies at a same interval. For example, if a spatial frequency included in the arrangement of the spatial frequencies after the re-arrangement is Xᵢ, the processing unit PU performs the re-arrangement by using the following Expression (1).

$$\begin{matrix}[ Expression 1 ] & \\ {X}_{i} = {x}_{0} + \frac{{x}_{N - 1} - {x}_{0}}{{N}_{s} - 1} \cdot i & ( 1 )\end{matrix}$$

Then, the processing unit PU calculates an intensity at the spatial frequency Xᵢ after the re-arrangement through linear interpolation. In this linear interpolation, the intensity Yᵢ is calculated by the following Expression (2).

$$\begin{matrix}[ Expression 2 ] & \\ {Y}_{i} = \frac{{y}_{j + 1} - {y}_{j}}{{x}_{j + 1} - {x}_{j}} \cdot ( {X}_{i} - {x}_{j} ) & ( 2 )\end{matrix}$$

Here, j denotes a maximum integer which allows a relationship of Xᵢ>xⱼ.

In a subsequent process S16, the processing unit PU performs Fourier transform (FFT processing) on the spectrum which is interpolated through the process S14.

Then, in a process S18, the processing unit PU filters a peak value of X=0 from the spectrum obtained in the process S16. For example, 0 is input to the intensity data Y in a range from X=0 to X=Z (preset value).

In a subsequent process S20, the processing unit PU extracts a peak value of X=2nd from the spectrum which is obtained in the process S18. For example, a maximum value of a peak is set to be Yᵢ, twenty (20) data points are extracted, starting from Yᵢ₋₁₀. This operation is for extracting data from the center of the peak downwards. For instance, if the maximum value of the peak is 1, the data points are extracted such that a range from this maximum value to 0.5 is included.

In a process S22, the processing unit PU performs second data interpolation (second linear interpolation). That is, the processing unit PU interpolates data of the 2nd peak obtained in the process S20. For example, the processing unit PU performs the linear interpolation on the data points with an interpolation number N_{A} at a same interval. The interpolation number N_{A} is set in advance based on a required degree of accuracy, for example. By way of example, the interpolation number N_{A} may be set based on the temperature measurement accuracy to be described later. For instance, in case that the first plate 16 is made of silicon, a peak interval Δ2nd after the FFT process becomes 0.4 μm/° C. Thus, if an accuracy of 1° C. is required, the interpolation number N_{A} is set such that the data interval becomes 0.4 μm. Alternatively, the interpolation number N_{A} may be set in consideration of a noise level of the system. For example, the data interpolation may be performed by using the following Expression (3).

$$\begin{matrix}[ Expression 3 ] & \\ {Y}_{i} = ( {y}_{j + 1} - {y}_{j} ) \cdot \frac{{X}_{i} - {X}_{j}}{{X}_{j + 1} - {X}_{j}} & ( 3 )\end{matrix}$$

Here, j denotes an index used for the arrangement of the intensities. The processing unit PU performs an operation of Expression (3) in a range from i=0 to i=N−1. That is, the operation of Expression (3) is performed on all the intervals between the twenty points obtained in the process S20. As described, the processing unit PU divides data intervals after the Fourier transform into a required division number and generates data according to the division number through the linear interpolation.

In a subsequent process S24, the processing unit PU extracts only a data range for use in a center calculation from the data which is interpolated in the process S22. By way of example, the processing unit PU sets a threshold value for use in the center calculation to be A %, and zero (0) is input to the intensity data Y equal to or below a maximum intensity (Y_{MAX})×A of the peak.

Then, in a subsequent process S26, the processing unit PU calculates a weighted center from the data which is interpolated in the process S24. In this process S26, the processing unit PU uses the following Expression (4).

$$\begin{matrix}[ Expression 4 ] & \\ 2 \cdot n \cdot d = \frac{{\sum }_{i = 1}^{N} ( {Y}_{i} \cdot {X}_{i} )}{{\sum }_{i = 1}^{N} {Y}_{i}} & ( 4 )\end{matrix}$$

Here, N denotes the number of data points after a center range is extracted. By using this Expression (4), the processing unit PU is capable of calculating the optical path length nd.

In the present exemplary embodiment, the processing unit PU is capable of calculating the optical path length of the first plate 16, that is, the optical path length of the first region R1, the optical path length of the second region R2 and the optical path length of the third region R3 in sequence, and is capable of calculating temperature calculation values of the first region R1, the second region R2 and the third region R3 based on the optical path lengths. The calculation of the temperature calculation values is performed based on the phenomenon that the optical path length nd varies depending on the temperature of the first plate 16. To elaborate, the processing unit PU calculates the temperature calculation value of each of the first region R1, the second region R2 and the third region R3 from the calculated optical path length nd by using a function or a table which specifies a relationship between the optical path length and the temperature.

In the plasma processing apparatus 10, if the processing unit PU calculates the optical path length of the first plate 16, that is, the optical path length of the first region R1, the optical path length of the second region R2 and the optical path length of the third region R3 and/or the temperature calculation values of the first region R1, the temperature calculation value of the second region R2 and the temperature calculation value of the third region R3, a controller Cnt is capable of performing various control operations.

The controller Cnt may be implemented by a programmable computer and is capable of controlling a magnitude of the high frequency power of the high frequency power supply HFS, a magnitude of the high frequency bias power of the high frequency power supply LFS, a gas exhaust amount of the gas exhaust device VS, a kind and a flow rate of the gas supplied to each supply path from the gas supply system GP, and a current amount applied to the coils of the electromagnet 30. To this end, the controller Cnt is capable of outputting control signals to the high frequency power supply HFS, the high frequency power supply LFS, the gas exhaust device VS, the valves and the flow rate controllers of the gas supply system GP and the current source connected to the coils of the electromagnet 30 according to a recipe inputted by an input device or stored in the memory.

Furthermore, the controller Cnt is capable of outputting an alarm according to the optical path length of the first region R1, the optical path length of the second region R2 and the optical path length of the third region R3 calculated by the processing unit PU. The optical path length of the first region R1, the optical path length of the second region R2 and the optical path length of the third region R3 reflect the plate thickness of the first region R1, the plate thickness of the second region R2 and the plate thickness of the third region R3, respectively. Accordingly, the controller Cnt is capable of outputting an alarm when the optical path length of each of the first region R1, the second region R2 and the third region R3 becomes a preset value, for example. Further, even if an alarm is not output, an operator of the plasma processing apparatus 10 may be capable of detect time for replacement of the first plate 16 based on the optical path length of the first region R1, the optical path length of the second region R2 and the optical path length of the third region R3.

Besides, the controller Cnt is also capable of controlling powers supplied to the first heater HT1, the second heater HT2 and the third heater HT3 from the first heater power supply HP1, the second heater power supply HP2 and the third heater power supply HP3, respectively, based on the temperature calculation value of the first region R1, the temperature calculation value of the second region R2 and the temperature calculation value of the third region R3 which are obtained by the processing unit PU.

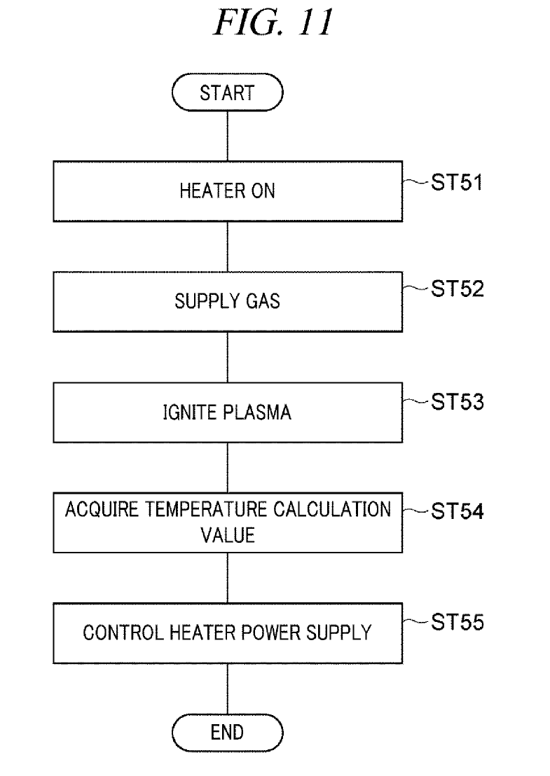

Now, several examples of an operation method of the plasma processing apparatus 10 as well as the control over the first heater power supply HP1, the second heater power supply HP2 and the third heater power supply HP3 performed by the controller Cnt will be explained. FIG. 11 is a flowchart for describing an example of the operation method of the plasma processing apparatus according to the exemplary embodiment.

As shown in FIG. 11, in a first example of the operation method of the plasma processing apparatus 10, the controller Cnt controls, in a process ST51 before plasma is generated, the first heater power supply HP1, the second heater power supply HP2 and the third heater power supply HP3 to supply powers such that the first heater HT1, the second heater HT2 and the third heater HT3 are turned ON. Further, the controller Cnt controls the chiller unit such that a coolant is supplied into the flow path 18f. As a result, the entire region of the first plate 16 is regulated to a substantially uniform temperature.

In a subsequent process ST52, the controller Cnt controls the gas supply system GP to supply a gas, and also operates the gas exhaust device VS. Accordingly, the gas is supplied into the processing space PS, and a pressure within the processing space PS is set to a preset value. Further, if the gas is supplied from the gas supply system GP, the gas also reaches a gap between the first plate 16 and the electrostatic attraction unit 19. The gas that has entered the gap serves as a heat transfer medium between the first plate 16 and the electrostatic attraction unit 19, so that the entire region of the first plate 16 is made to approach a target temperature.

In a subsequent process ST53, the controller Cnt controls the high frequency power supply HFS to supply the high frequency power to generate plasma. At this time, the controller Cnt may also control the high frequency power supply LFS to supply the high frequency bias power and the DC power supply NP to supply the negative DC voltage to the upper electrode structure US.

Then, in a process ST54, the controller Cnt acquires the temperature calculation value of the first region R1, the temperature calculation value of the second region R2 and the temperature calculation value of the third region R3 which are calculated by the processing unit PU. In a subsequent process ST55, the controller Cnt controls the first heater power supply HP1, the second heater power supply HP2 and the third heater power supply HP3 based on the temperature calculation value of the first region R1, the temperature calculation value of the second region R2 and the temperature calculation value of the third region R3. By way of example, the controller Cnt controls the first heater power supply HP1, the second heater power supply HP2 and the third heater power supply HP3 based on the temperature calculation value of the first region R1, the temperature calculation value of the second region R2 and the temperature calculation value of the third region R3 such that the temperature of the first region R1, the temperature of the second region R2 and the temperature of the third region R3 become substantially same. Further, the process ST54 and the process ST55 may be repeated until a plasma process of a single sheet of wafer W is completed.

In the plasma processing apparatus 10, there may be generated plasma having a plasma density distribution which varies in the radial direction with respect to the axis line AX. For example, there may be generated plasma having a high density in the vicinity of the axis line AX and having a lower density as it goes farther from the axis line AX. Accordingly, the amount of heat input from the plasma to the first plate 16 has a distribution which varies in the radial direction. Further, due to this plasma density distribution, the amount of first plate 16 etched in the plasma process also has a distribution which varies in the radial direction. That is, as the plasma process is performed, the first plate 16 becomes to have a thickness distribution. This thickness distribution of the first plate 16 causes a varying temperature distribution of the first plate 16. According to the aforementioned operation method of the plasma processing apparatus 10, however, it is possible to correct, through the process ST55, the temperature distribution on the first plate 16 which varies in the radial direction.

For example, in a plasma generation period, the power supplied to the first heater HT1 from the first heater power supply HP1 may be set to be highest; the power supplied to the second heater HT2 from the second heater power supply HP2 may be set to be second highest; and the power supplied to the third heater HT3 from the third heater power supply HP3 may be set to be lowest or turned OFF through the process ST55. Further, in the plasma generation period, the coolant may be continuously supplied into the flow path 18f from the chiller unit.

Now, a second example of the operation method of the plasma processing apparatus 10 will be explained. In the second example, it is assumed that a multiple number of wafers W are processed continuously, i.e., in sequence. In this second example, in the plasma process, the controller Cnt controls the first heater power supply HP1, the second heater power supply HP2 and the third heater power supply HP3 based on the temperature calculation value of the first region R1, the temperature calculation value of the second region R2 and the temperature calculation value of the third region R3, which are obtained by the processing unit PU, such that the temperature of the first region R1, the temperature of the second region R2 and the temperature of the third region R3 become preset temperatures.

In case of processing the multiple number of wafers W in sequence, a plasma state when processing each wafer W may be varied. For example, a plasma state when processing the first wafer W may be different from a plasma state when processing a subsequent wafer W. This phenomenon is referred to as “first wafer effect.” Due to this phenomenon, the temperature of the upper electrode structure US may be varied while processing the respective wafers W. In the second example, in case where the wafers W are processed continuously, outputs of the first heater power supply HP1, the second heater power supply HP2 and the third heater power supply HP3 are controlled such that the temperature of the first region R1, the temperature of the second region R2 and the temperature of the third region R3 become the preset temperature. Thus, it is possible to reduce a difference in the temperatures of the upper electrode structure US while processing the multiple number of wafers W continually.

Now, a third example of the operation method of the plasma processing apparatus 10 will be discussed. In this third example, it is assumed that a ratio of an amount of a deposition gas to an amount of an etching gas, which are included in each of a first gas discharged from the gas discharge openings 16i of the first region R1, a second gas discharged from the gas discharge openings 16j of the second region R2 and a third gas discharged from the gas discharge openings 16j of the third region R3, is different between the first, second and third gases. The etching gas is a corrosion gas such as a halogen element and may be, by way of non-limiting example, a fluorocarbon gas. Further, the deposition gas is a gas adhering to the first plate 16 or altering the first plate 16. By way of non-limiting example, the deposition gas may be an oxygen (O₂) gas.

In this third example, the controller Cnt controls the first heater power supply HP1, the second heater power supply HP2 and the third heater power supply HP3 based on the ratio of the amount of the deposition gas to the amount of the etching gas included in each of the first gas, the second gas and the third gas such that the temperature of the first region R1, the temperature of the second region R2 and the temperature of the third region R3 are increased. Further, the controller Cnt may control the outputs of the first heater power supply HP1, the second heater power supply HP2 and the third heater power supply HP3 based on the temperature calculation value of the first region R1, the temperature calculation value of the second region R2 and the temperature calculation value of the third region R3 calculated by the processing unit PU.

Here, if a deposit originated from the deposition gas adheres to the surface of the first plate 16, the deposit may become a micro mask, and there may occur a phenomenon that the surface of the first plate 16 is etched, that is, a so-called “black silicon” is formed. Formation of this black silicon becomes conspicuous depending on how much deposition gas is included in the gas, that is, depending on the ratio of the deposition gas in the certain gas. Meanwhile, an adhesion amount of the deposit decreases as the temperature of the first plate 16 increases.

In the third example, since the temperatures of the first region R1, the second region R2 and the third region R3 are controlled based on the amount of the deposition gas included in each of the gases discharged from the corresponding gas discharge openings of the first to third regions R1 to R3, it is possible to suppress the formation of black silicon in these regions.

Now, an experimental example 1 in which an amount of the third region R3 of the first plate 16 etched by performing the plasma process in the plasma processing apparatus 10, that is, an etching amount, is calculated based on the optical path length nd obtained by the third acquisition unit OS3 and the processing unit PU will be explained. In this experimental example 1, the plasma process is performed under the following conditions while varying a processing time as a parameter.

<Conditions for Plasma Process>

Gas: CF-based gas (50 scc), Ar gas (400 sccm), O₂ gas (30 sccm)

High frequency power supply HFS: 40 MHz, 1200 W

High frequency power supply LFS: 13 MHz, 4500 W

Processing time: 3 types of 10 min, 20 min, 50 min

Then, a state where the temperature of the first plate 16 is stabilized after the plasma generation is completed is determined to be a state where the temperature of the first plate 16 becomes 150° C. It is assumed that a refractive index of the first plate 16 in this state is 3.7. From the optical path length nd of the third region R3, the plate thickness of the third region R3, that is, nd/3.7 is calculated, and the etching amount of the third region R3 is calculated from the plate thickness. As a result, the etching amount is found to be 0.4 μm, 0.9 μm, 1.9 μm when the processing time is 10 min, 20 min and 50 min, respectively. Thus, it is found out that the optical path length nd corresponding to the plate thickness of each region of the first plate 16 can be calculated by the aforementioned acquisition units and the processing unit PU.

Subsequently, an experimental example 2 for evaluating the plasma processing apparatus 10 will be discussed. In this experimental example 2, the first heater power supply HP1, the second heater power supply HP2 and the third heater power supply HP3 are controlled such that a target temperature of the first plate 16 becomes 150° C. Then, as shown in the following conditions, a process of supplying the gas from the gas supply system GP, a process of generating plasma for a preset time and then a process of stopping the plasma generation are repeated plural times, and the temperature of the third region R3 is measured.

<Conditions>

Gas: CF-based gas (50 scc), Ar gas (400 sccm), O₂ gas (30 sccm)

High frequency power supply HFS: 40 MHz, 1200 W

High frequency power supply LFS: 13 MHz, 4500 W

Voltage applied from DC power supply NP: 3 types of 0 V, 150 V, 300 V

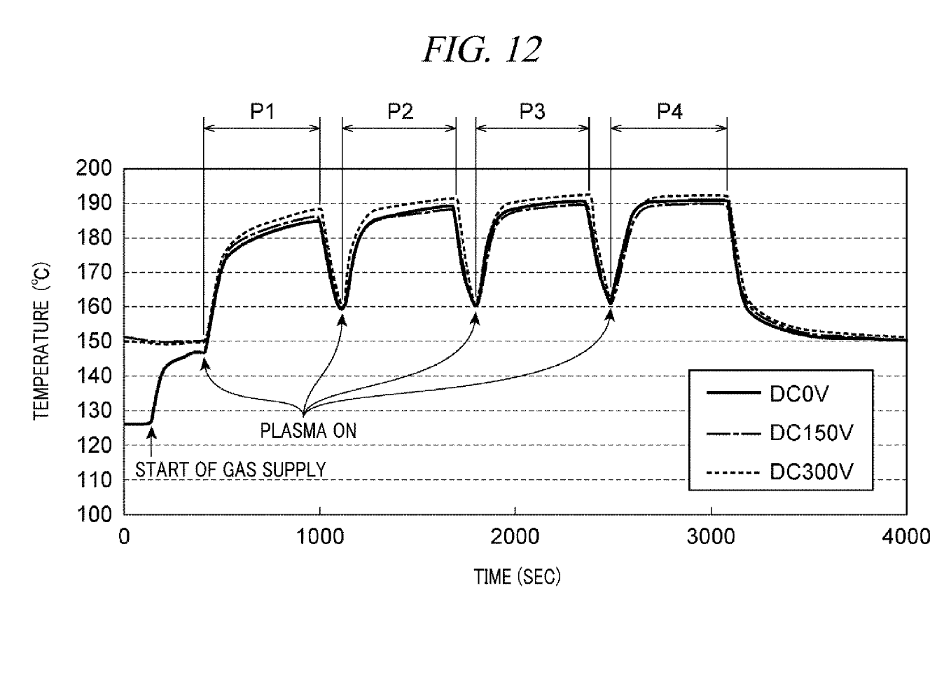

FIG. 12 is a graph showing a result of the experimental example 2. In FIG. 12, a horizontal axis represents time, and a vertical axis indicates the temperature of the third region R3. As can be seen from FIG. 12, even if the first heater power supply HP1, the second heater power supply HP2 and the third heater power supply HP3 are controlled according to the target temperature, the temperature of the third region R3 is found to be about 125° C., lower than the target temperature of 150° C. If the supply of the gas is begun afterwards, the temperature of the third region R3 approaches the target temperature of 150° C. As can be seen from this experiment, it is found out that the gas that has reached the gap between the first plate 16 and the electrostatic attraction unit 19 serves as a heat transfer medium, and it is also found out that thermal conduction between the first plate 16 and the electrostatic attraction unit 19 can be achieved even when the surface 19s made of ceramic serves as an attraction surface.

Further, in FIG. 12, a period P1, a period P2, a period P3 and a period P4 are periods from when the plasma generation is begun (indicated by “Plasma ON” in the figure), that is, from when the supply of the high frequency powers from the high frequency power supply HFS and the high frequency power supply LFS is begun to when the plasma generation is ended, that is, when the supply of the high frequency powers from the high frequency power supply HFS and the high frequency power supply LFS is stopped. As depicted in FIG. 12, the highest temperature of the third region R3 in the period P1, which is a period of the first plasma process, is found to be lower than the highest temperature of the third region R3 in the other periods. From this result, it is found out that the highest temperature of the first plate 16 becomes low in the first plasma process. This phenomenon may cause a discrepancy between the plasma process upon the first wafer and a plasma process upon a subsequent wafer in case where the plasma process is performed on a multiple number of wafers in sequence. According to the plasma processing apparatus 10, however, since the first heater power supply HP1, the second heater power supply HP2 and the third heater power supply HP3 can be controlled such that the first region R1, the second region R2 and the third region R3 reach the preset temperature during the plasma process, adverse influence from this phenomenon can be suppressed.

So far, the various exemplary embodiments have been described. However, the exemplary embodiments are not limiting, and various changes and modifications may be made. For example, though the first plate 16 of the above-described exemplary embodiment has been described to have three regions, the first plate 16 may have four or more concentric regions, and the upper electrode structure US may have four or more supply paths for supplying the gas into these four or more regions individually.

### EXPLANATION OF REFERENCE NUMERALS

10: Plasma processing apparatus
12: Processing vessel
14: Mounting table
US: Upper electrode structure
16: First plate
R1: First region
16i: Gas discharge opening
R2: Second region
16j: Gas discharge opening
R3: Third region
16k: Gas discharge opening
18: Second plate
18f: Flow path (for coolant)
19: Electrostatic attraction unit
19m: Main body
19e: Electrode
19s: Surface
D13: Gas diffusion space (first gas diffusion space)
D23: Gas diffusion space (second gas diffusion space)
D33: Gas diffusion space (Third gas diffusion space)
HT1: First heater
HT2: Second heater
HT3: Third heater
HP1: First heater power supply
HP2: Second heater power supply
HP3: Third heater power supply
L11: Gas line (first gas line)
D11: Gas diffusion space (Fourth gas diffusion space)
L12: Gas line (second gas line)
D12: Gas diffusion space (Fifth gas diffusion space)
L13: Gas line (Third gas line)
L21: Gas line (Fourth gas line)
D21: Gas diffusion space (Sixth gas diffusion space)
L22: Gas line (Fifth gas line)
D22: Gas diffusion space (Seventh gas diffusion space)
L23: Gas line (Sixth gas line)
L31: Gas line (Seventh gas line)
D31: Gas diffusion space (Eighth gas diffusion space)
L32: Gas line (Eighth gas line)
D32: Gas diffusion space (Ninth gas diffusion space)
L33: Gas line (Ninth gas line)
GP: Gas supply system
HFS: High frequency power supply
LFS: High frequency power supply
OS1: First acquisition unit
OS2: Second acquisition unit
OS3: Third acquisition unit
82: Light source
84: Circulator
86: Optical fiber
88: Optical element
90: Spectrometer
PU: Processing unit
Cnt: Controller

1. An upper electrode structure of a capacitively coupled plasma processing apparatus, comprising:
a first plate having a first region, a second region concentrically surrounding the first region, and a third region concentrically surrounding the second region, each of the first region, the second region and the third region being provided with a multiple number of gas discharge openings;
a second plate provided with a flow path for a coolant; and
an electrostatic attraction unit provided between the first plate and the second plate and configured to attract the first plate,
wherein the electrostatic attraction unit is equipped with a first heater provided between the second plate and the first region, a second heater provided between the second plate and the second region and a third heater provided between the second plate and the third region,
the electrostatic attraction unit provides, along with the second plate, a first supply path through which a gas is supplied into the first region, a second supply path through which a gas is supplied into the second region, and a third supply path through which a gas is supplied into the third region, and
a first gas diffusion space included in the first supply path, a second gas diffusion space included in the second supply path and a third gas diffusion space included in the third supply path are formed in the electrostatic attraction unit.

2. The upper electrode structure of claim 1,
wherein the electrostatic attraction unit includes a main body made of ceramic and an electrode for electrostatic attraction, and
a surface of the main body made of ceramic forms an attraction surface of the first plate.

3. The upper electrode structure of claim 1,
wherein the first supply path is formed of a first gas line, a fourth gas diffusion space, a plurality of second gas lines, a fifth gas diffusion space, a plurality of third gas lines and the first gas diffusion space which are connected in sequence,
the plurality of second gas lines and the plurality of third gas lines are arranged in a circumferential direction with respect to a central axis line of the first region, and have a conductance lower than a conductance of the first gas diffusion space, a conductance of the fourth gas diffusion space and a conductance of the fifth gas diffusion space,
the second supply path is formed of a fourth gas line, a sixth gas diffusion space, a plurality of fifth gas lines, a seventh gas diffusion space, a plurality of sixth gas lines and the second gas diffusion space which are connected in sequence,
the plurality of fifth gas lines and the plurality of sixth gas lines are arranged in the circumferential direction with respect to the central axis line, and have a conductance lower than a conductance of the second gas diffusion space, a conductance of the sixth gas diffusion space and a conductance of the seventh gas diffusion space,
the third supply path is formed of a seventh gas line, an eighth gas diffusion space, a plurality of eighth gas lines, a ninth gas diffusion space, a plurality of ninth gas lines and the third gas diffusion space which are connected in sequence, and
the plurality of eighth gas lines and the plurality of ninth gas lines are arranged in the circumferential direction with respect to the central axis line, and have a conductance lower than a conductance of the third gas diffusion space, a conductance of the eighth gas diffusion space and a conductance of the ninth gas diffusion space.

4. A capacitively coupled plasma processing apparatus, comprising:
a processing vessel;
a mounting table, having a lower electrode, provided within the processing vessel; and
an upper electrode structure as claimed in claim 1.

5. The plasma processing apparatus of claim 4, further comprising:
a first acquisition unit configured to irradiate light from a light source to the first region of the first plate and acquire a wavelength spectrum of reflection light from a front surface and a rear surface of the first region;
a second acquisition unit configured to irradiate light from a light source to the second region of the first plate and acquire a wavelength spectrum of reflection light from a front surface and a rear surface of the second region;
a third acquisition unit configured to irradiate light from a light source to the third region of the first plate and acquire a wavelength spectrum of reflection light from a front surface and a rear surface of the third region; and
a processing unit configured to calculate an optical path length between the front surface and the rear surface of the first region, an optical path length between the front surface and the rear surface of the second region and an optical path length between the front surface and the rear surface of the third region based on the wavelength spectrum acquired by the first acquisition unit, the wavelength spectrum acquired by the second acquisition unit and the wavelength spectrum acquired by the third acquisition unit, respectively.

6. The plasma processing apparatus of claim 5, further comprising:
a first heater power supply connected to the first heater;
a second heater power supply connected to the second heater;
a third heater power supply connected to the third heater; and
a controller configured to control the first heater power supply, the second heater power supply and the third heater power supply,
wherein the processing unit calculates a temperature calculation value of the first region, a temperature calculation value of the second region and a temperature calculation value of the third region based on the optical path length of the first region, the optical path length of the second region and the optical path length of the third region, respectively, and
the controller controls the first heater power supply, the second heater power supply and the third heater power supply based on the temperature calculation value of the first region, the temperature calculation value of the second region and the temperature calculation value of the third region, respectively.

7. The plasma processing apparatus of claim 6,
wherein the controller controls the first heater power supply, the second heater power supply and the third heater power supply such that a temperature of the first region, a temperature of the second region and a temperature of the third region are substantially same.

8. The plasma processing apparatus of claim 6,
wherein the controller controls, when a plasma process is performed, the first heater power supply, the second heater power supply and the third heater power supply such that a temperature of the first region, a temperature of the second region and a temperature of the third region reach a preset temperature.

9. The plasma processing apparatus of claim 6,
wherein the controller controls the first heater power supply, the second heater power supply and the third heater power supply such that a temperature of the first region, a temperature of the second region and a temperature of the third region are respectively increased based on a ratio of an amount of a deposition gas to an amount of an etching gas, which are included in each of a first gas discharged from the gas discharge openings of the first region, a second gas discharged from the gas discharge openings of the second region and a third gas discharged from the gas discharge openings of the third region.

10. An operation method of a plasma processing apparatus as claimed in claim 6, comprising:
controlling, when a plasma process is performed, the first heater power supply, the second heater power supply and the third heater power supply such that a temperature of the first region, a temperature of the second region and a temperature of the third region are substantially same.

11. An operation method of a plasma processing apparatus as claimed in claim 6, comprising:
controlling, when a plasma process is performed, the first heater power supply, the second heater power supply and the third heater power supply such that a temperature of the first region, a temperature of the second region and a temperature of the third region reach a preset temperature.

12. An operation method of a plasma processing apparatus as claimed in claim 6, comprising:
controlling the first heater power supply, the second heater power supply and the third heater power supply such that a temperature of the first region, a temperature of the second region and a temperature of the third region are increased based on a ratio of an amount of a deposition gas to an amount of an etching gas, which are included in each of a first gas discharged from the gas discharge openings of the first region, a second gas discharged from the gas discharge openings of the second region and a third gas discharged from the gas discharge openings of the third region.
